(19) United States
(12) Patent Application Publication
(10) Pub. No.: US 2023/0223496 A1
(43) Pub. Date: Jul. 13, 2023

(54) LIGHT-EMITTING ELEMENT, METHOD OF FABRICATING THE LIGHT-EMITTING ELEMENT, AND DISPLAY DEVICE

(71) Applicant: Samsung Display Co., LTD., Yongin-si (KR)

(72) Inventors: Jun Hong PARK, Suwon-si (KR); Tae Gyun KIM, Hwaseong-si (KR); Eui Suk JUNG, Seoul (KR)

(73) Assignee: Samsung Display Co., LTD., Yongin-si (KR)

(21) Appl. No.: 17/964,434

(22) Filed: Oct. 12, 2022

(30) Foreign Application Priority Data
Jan. 7, 2022 (KR) 10-2022-0002720

(51) Int. Cl. H01L 33/38; H01L 33/62; H01L 33/00; H01L 33/20

(52) U.S. Cl. CPC H01L 33/382; H01L 33/62; H01L 33/005; H01L 33/20; H01L 2933/0016; H01L 2933/0066

(57) ABSTRACT

A light-emitting element includes a first semiconductor layer doped with an n-type dopant, a second semiconductor layer disposed on the first semiconductor layer and doped with a p-type dopant, a light-emitting layer disposed between the first and second semiconductor layers, an electrode layer disposed on the second semiconductor layer, an insulating film surrounding at least an outer surface of the light-emitting layer, and a void formed on the first semiconductor layer, the void extending in a direction in which the first semiconductor layer, the light-emitting layer, and the second semiconductor layer are disposed.

### CROSS-REFERENCE TO RELATED APPLICATION(S)

This application claims priority to and benefits of Korean Patent Application No. 10-2022-0002720 under 35 U.S.C. 119, filed on Jan. 7, 2022 in the Korean Intellectual Property Office, the entire contents of which are herein incorporated by reference.

### BACKGROUND

### 1. Field

The disclosure relates to a light-emitting element, a method of fabricating the light-emitting element, and a display device.

### 2. Description of the Related Art

Display devices are becoming more important with developments in multimedia technology. Accordingly, various display devices such as an organic light-emitting diode (OLED) display device, a liquid crystal display (LCD) device, and the like have been used.

There are self-luminous display devices including light-emitting elements. Examples of the self-luminous display devices include an organic light-emitting display device using an organic material as a light-emitting material or an inorganic light emitting display device using an inorganic material as a light-emitting material.

### SUMMARY

Aspects of the disclosure provide a light-emitting element having a void or a through hole formed therein to extend from one end to the other end thereof and a method of fabricating the light-emitting element.

Aspects of the disclosure provide a display device having an improved degree of alignment by including such light-emitting elements.

However, aspects of the disclosure are not restricted to those set forth herein. The above and other aspects of the disclosure will become more apparent to one of ordinary skill in the art to which the disclosure pertains by referencing the detailed description of the disclosure given below.

According to an embodiment of the disclosure, a light-emitting element may include a first semiconductor layer doped with an n-type dopant, a second semiconductor layer disposed on the first semiconductor layer and doped with a p-type dopant, a light-emitting layer disposed between the first and second semiconductor layers, an electrode layer disposed on the second semiconductor layer, an insulating film surrounding at least an outer surface of the light-emitting layer, and a void formed on the first semiconductor layer, the void extending in a direction in which the first semiconductor layer, the light-emitting layer, and the second semiconductor layer are disposed.

The light-emitting element may further comprise a filler layer disposed in the void, the filler layer having a lower specific gravity than a lower specific gravity of the first semiconductor layer, a lower specific gravity of the light-emitting layer, and a lower specific gravity of the second semiconductor layer.

The filler layer may include an insulating material different from the insulating film.

The filler layer may include polyimide, and the insulating film may include at least one of silicon oxide, silicon nitride, and silicon oxynitride.

The filler layer may include a porous material.

The void may penetrate the light-emitting layer and the second semiconductor layer and be formed by etching part of the first semiconductor layer, and the filler layer may be in contact with the first semiconductor layer, the light-emitting layer, and the second semiconductor layer.

A top surface of the filler layer may physically contact a bottom surface of the electrode layer.

The void and the filler layer may be shorter than the light-emitting element.

The void may be formed in the first semiconductor layer and be shorter than the light-emitting element.

The void may extend from an interface between the light-emitting layer and the first semiconductor layer, and a top surface of the filler layer may physically contact a bottom surface of the light-emitting layer.

The void may be formed only in the first semiconductor layer to be spaced apart from the light-emitting layer, and the filler layer may not physically contact the light-emitting layer.

The void may form a through hole, which may penetrate both a top surface and a bottom surface of the light-emitting element through the first semiconductor layer, the light-emitting layer, the second semiconductor layer, and the electrode layer.

The through hole and the light-emitting element may have a same length.

According to an embodiment of the disclosure, a display device may include a first electrode and a second electrode disposed on a substrate to be spaced apart from each other, a first insulating layer disposed on the first electrode and the second electrode, a light-emitting element disposed on the first insulating layer, the light-emitting element having a first end portion disposed on the first electrode, and a second end portion disposed on the second electrode, a second insulating layer disposed on the light-emitting element, a first connecting electrode disposed on the first electrode, on the second insulating layer, the first connecting electrode electrically contacting the first end portion, a second connecting electrode disposed on the second electrode, on the second insulating layer, the second connecting electrode electrically contacting the second end portion, and a third insulating layer disposed on the second insulating layer and the second connecting electrode, below the first connecting electrode. The light-emitting element may include a first semiconductor layer, a second semiconductor layer, a light-emitting layer, which may be disposed between the first semiconductor layer and the second semiconductor layer, an electrode layer, which may be disposed on the second semiconductor layer, an insulating film, which surrounds at least an outer surface of the light-emitting layer, and a void, which may be formed in the first semiconductor layer, the light-emitting layer, and the second semiconductor layer and may extend in a length direction of the light-emitting element.

The void may penetrate the second semiconductor layer and the light-emitting layer and meet a bottom surface of the electrode layer, and the light-emitting element may further include a filler layer, which may be disposed in the void.

The void may penetrate the first semiconductor layer and the electrode layer to form a through hole, which penetrates both the first and second end portions of the light-emitting element.

According to an embodiment of the disclosure, a method of fabricating light-emitting elements may include preparing a base substrate and forming a first semiconductor material layer, a light-emitting material layer, and a second semiconductor material layer on the base substrate, performing a first etching step of forming first holes by etching the first semiconductor material layer, the light-emitting material layer, and the second semiconductor material layer in a direction perpendicular to a top surface of the base substrate, forming a filler material layer in each of the first holes and forming an electrode material layer on the second semiconductor material layer, forming second holes by etching the first semiconductor material layer, the light-emitting material layer, the second semiconductor material, and the electrode material layer in the direction perpendicular to the top surface of the base substrate, thereby forming semiconductor rods, which may be spaced apart from one another, and separating the semiconductor rods with the insulating material layer formed thereon from the base substrate.

The performing the first etching step may comprise forming the first holes to penetrate the second semiconductor material layer and the light-emitting material layer, but not the first semiconductor material layer.

The forming the semiconductor rods may comprise forming mask layers, which may be spaced apart from one another, on the electrode material layer and performing a second etching step of etching parts where the mask layers may not be disposed, and the mask layers may overlap the filler material layer.

The performing the first etching process may comprise forming photoresist layers or hard mask layers on the second semiconductor material layer, and dry-etching parts where the photoresist layers or the hard mask layers may not be disposed.

According to the aforementioned and other embodiments of the disclosure, voids or through holes can be formed in light-emitting elements. Each of the light-emitting elements may include a void and may further include a filler layer having a lower specific gravity than semiconductor layers. The light-emitting elements may include a semiconductor material with a high specific gravity, but may have a relatively low specific gravity due to the presence of the voids or the through holes therein.

In a display device, the light-emitting elements can be properly aligned on electrodes that may be spaced apart from one another, during inkjet printing. As the number of light-emitting elements that may be properly aligned per unit pixel increases, the product quality of the display device and the efficiency of the fabrication of the display device can be improved.

It should be noted that the effects of the disclosure are not limited to those described above, and other effects of the disclosure will be apparent from the following description.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a display device according to an embodiment of the disclosure;

FIG. 2 is a schematic plan view of a pixel of the display device;

FIG. 3 is a schematic cross-sectional view taken along line E1-E1′ of FIG. 2;

FIG. 4 is a schematic cross-sectional view taken along line E2-E2′ of FIG. 2;

FIG. 5 is a schematic perspective view of a light-emitting element according to an embodiment of the disclosure;

FIG. 6 is a schematic cross-sectional view of the light-emitting element of FIG. 5;

FIG. 7 is a schematic cross-sectional view illustrating an area in the display device of FIG. 2 where a light-emitting element may be disposed;

FIGS. 8 through 19 are schematic cross-sectional views illustrating a method of fabricating a light-emitting element according to an embodiment of the disclosure;

FIG. 20 is a schematic cross-sectional view illustrating a method of fabricating a light-emitting element according to another embodiment of the disclosure;

FIG. 21 is a schematic cross-sectional view of a light-emitting element according to another embodiment of the disclosure;

FIG. 22 is a schematic cross-sectional view illustrating a method of fabricating the light-emitting element of FIG. 21;

FIG. 23 is a schematic cross-sectional view of a light-emitting element according to another embodiment of the disclosure;

FIG. 24 is a schematic cross-sectional view of a light-emitting element according to another embodiment of the disclosure;

FIGS. 25 through 27 are schematic cross-sectional views illustrating a method of fabricating the light-emitting element of FIG. 24;

FIG. 28 is a schematic cross-sectional view of a light-emitting element according to another embodiment of the disclosure;

FIG. 29 is a schematic perspective view of a light-emitting element according to another embodiment of the disclosure;

FIG. 30 is a schematic cross-sectional view of the light-emitting element of FIG. 29;

FIG. 31 is a schematic cross-sectional view illustrating an area in a display device including the light-emitting element of FIG. 30 where the light-emitting element of FIG. 30 is disposed; and

FIGS. 32 through 38 are schematic cross-sectional views illustrating a method of fabricating the light-emitting element of FIG. 29.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

As used herein, the singular forms, “a,” “an,” and “the” are intended to include the plural forms as well, unless the context clearly indicates otherwise.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

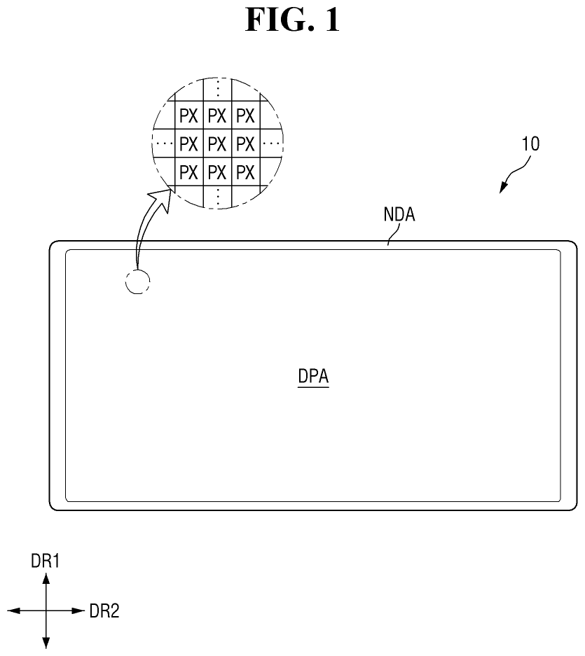

FIG. 1 is a schematic plan view of a display device according to an embodiment of the disclosure.

Referring to FIG. 1, a display device 10 may display a moving or still image. The display device 10 may refer to nearly all types of electronic devices that provide a display screen. Examples of the display device 10 may include a television (TV), a notebook computer, a monitor, a billboard, an Internet-of-Things (IoT) device, a mobile phone, a smartphone, a tablet personal computer (PC), an electronic watch, a smartwatch, a watchphone, a head-mounted display (HMD), a mobile communication terminal, an electronic notepad, an electronic book (e-book), a portable multimedia player (PMP), a navigation device, a gaming console, a digital camera, a camcorder, and the like.

The display device 10 may include a display panel that provides a display screen. Examples of the display panel of the display device 10 may include an inorganic light-emitting diode (ILED) display panel, an organic light-emitting diode (OLED) display panel, a quantum-dot light-emitting diode (QLED) display panel, a plasma display panel (PDP), a field-emission display (FED) panel, and the like. The display panel of the display device 10 will hereinafter be described as being, for example, an ILED display panel, but the disclosure is not limited thereto. For example, various other display panels are also applicable to the display panel of the display device 10.

The shape of the display device 10 may vary. For example, the display device 10 may have a rectangular shape that extends longer in a horizontal direction than in a vertical direction, a rectangular shape that extends longer in the vertical direction than in the horizontal direction, a square shape, a tetragonal shape with rounded corners, a non-tetragonal polygonal shape, or a circular shape. The shape of a display area DPA of the display device 10 may be similar to the shape of the display device 10. FIG. 1 illustrates that the display device 10 and the display area DPA both have a rectangular shape that extends in a second direction DR2.

The display device 10 may include the display area DPA and a non-display area NDA. The display area DPA may be an area in which a screen may be displayed, and the non-display area NDA may be an area in which a screen may not be displayed. The display area DPA may also be referred to as an active area, and the non-display area NDA may also be referred to as an inactive area. The display area DPA may occupy the middle part of the display device 10.

The display area DPA may include pixels PX. The pixels PX may be arranged in row and column directions. Each of the pixels PX may have a rectangular or square shape in a plan view, but the disclosure is not limited thereto. In other embodiments, each of the pixels PX may have a rhombus shape having sides inclined with respect to a particular direction. The pixels PX may be arranged in a stripe fashion or an island fashion. Each of the pixels PX may include one or more light-emitting elements, which emit light of a particular wavelength range.

The non-display area NDA may be disposed around the display area DPA. The non-display area NDA may surround the entire display area DPA or part of the display area DPA. The display area DPA may have a rectangular shape, and the non-display area NDA may be disposed adjacent to four sides of the display area DPA. The non-display area NDA may form the bezel of the display device 10. Lines or circuit drivers included in the display device 10 may be disposed in the non-display area NDA, or external devices may be mounted in the non-display area NDA.

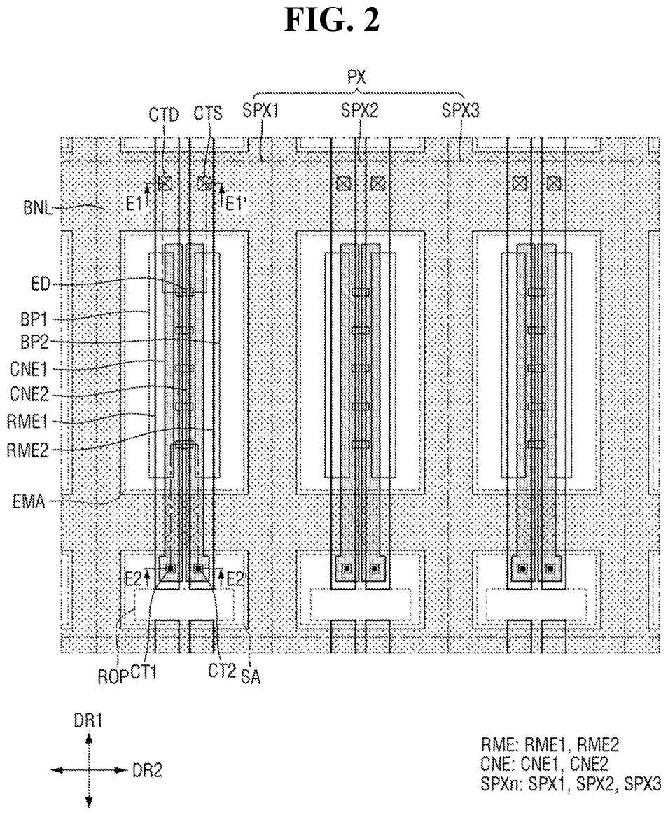

FIG. 2 is a schematic plan view of a pixel of the display device of FIG. 1. FIG. 2 is a plan view illustrating the layout of electrodes RME, bank patterns (BP1 and BP2), a bank layer BNL, light-emitting elements ED, and connecting electrodes CNE in a pixel PX of the display device 10.

Referring to FIG. 2, a pixel PX may include subpixels SPXn. For example, the pixel PX may include first through third subpixels SPX1 through SPX3. The first subpixel SPX1 may emit first-color light, the second subpixel SPX2 may emit second-color light, and the third subpixel SPX3 may emit third-color light. For example, the first-color light, the second-color light, and the third-color light may be blue light, green light, and red light, respectively, but the disclosure is not limited thereto. In other embodiments, the subpixels SPXn may all emit light of the same color. For example, the subpixels SPXn may all emit blue light. FIG. 2 illustrates that the pixel PX may include three subpixels SPXn, but the disclosure is not limited thereto. In other embodiments, the pixel PX may include more than three subpixels SPXn.

Each of the subpixels SPXn may include an emission area EMA and a non-emission area. The emission area EMA may be an area that outputs light of a particular wavelength range due to the presence of light-emitting elements ED therein. The non-emission area may be an area that may not be reached by light emitted by the light-emitting elements ED and does not output light due to the absence of light-emitting elements therein.

The emission area EMA may include a region where arrays of light-emitting elements ED may be disposed and a region around the array of light-emitting elements ED that outputs light emitted by the light-emitting elements ED. For example, the emission area EMA may also include a region that outputs light emitted by the light-emitting elements ED and then reflected or refracted by other members. Multiple light-emitting elements ED may be disposed in each of the subpixels SPXn to form an emission area EMA including a region where the light-emitting elements ED may be disposed and the surroundings of the region where the light-emitting elements ED may be disposed.

FIG. 2 illustrates that the emission areas EMA of the first through third subpixels SPX1 through SPX3 may have the same size. In some embodiments, the emission areas EMA of the subpixels SPXn may have different sizes depending on the color or the wavelength of light emitted by light-emitting elements ED.

Each of the subpixels SPXn may further include a subarea SA, which may be disposed in the non-emission area of the corresponding subpixel SPXn. The subarea SA may be disposed on the lower side of the emission area EMA. The emission area EMA and the subarea SA may be arranged one after another in the first direction DR1, and the subarea SA may be disposed between two emission areas EMA of two adjacent subpixels SPXn that may be spaced apart from each other in the first direction DR1. For example, emission areas EMA and subareas SA may be alternately arranged in the first direction DR1, and emission areas EMA or subareas SA may be repeatedly arranged in the second direction DR2. However, the disclosure is not limited to this example. For example, the emission areas EMA and the subareas SA of the subpixels SPXn may have a different layout from that illustrated in FIG. 2.

As no light-emitting elements ED may be disposed in the subarea SA of each of the subpixels SPXn, no light may be output from the subarea SA of each of the subpixels SPXn, but electrodes RME may be disposed in part in the subarea SA of each of the subpixels SPXn. The electrodes RME of each of the subpixels SPXn may be separated from electrodes RME from another subpixel SPXn by a separation part ROP of the subarea SA of the corresponding subpixel SPXn.

The display device 10 may include, in each of the subpixels SPXn, electrodes RME, bank patterns (BP1 and BP2), a bank layer BNL, light-emitting elements ED, and connecting electrodes CNE.

The bank patterns (BP1 and BP2) may be disposed in the emission area EMA of each of the subpixels SPXn. The bank patterns (BP1 and BP2) may have a width in the second direction DR2 and may extend in the first direction DR1.

For example, the bank patterns (BP1 and BP2) may include first and second bank patterns BP1 and BP2, which may be disposed in the emission area EMA of each of the subpixels SPXn to be spaced apart from one another in the second direction DR2. The first bank pattern BP1 may be disposed on a first side, in the second direction DR2, of the center of the emission area EMA, for example, on the left side of the emission area EMA, and the second bank pattern BP2 may be disposed on a second side, in the second direction DR2, of the center of the emission area EMA, for example, on the right side of the emission area EMA. The first and second bank patterns BP1 and BP2 may be arranged one after another in the second direction DR2 and may be disposed as islands in the display area DPA. The light-emitting elements ED may be disposed between the first and second bank patterns BP1 and BP2.

The lengths, in the first direction DR1, of the first and second bank patterns BP1 and BP2 may be the same and may be less than the length, in the first direction DR1, of the emission area EMA, surrounded by the bank layer BNL. The first and second bank patterns BP1 and BP2 may be spaced apart from parts of the bank layer BNL that extend in the second direction DR2, but the disclosure is not limited thereto. The bank patterns (BP1 and BP2) may be integrally formed with the bank layer BNL or may partially overlap the parts of the bank layer BNL that extend in the second direction DR2, in which case, the length, in the first direction DR1, of the bank patterns (BP1 and BP2) may be the same as, or greater than the length, in the first direction DR1, of the emission area EMA, surrounded by the bank layer BNL

The first and second bank patterns BP1 and BP2 may have the same width in the second direction DR2, but the disclosure is not limited thereto. In other embodiments, the first and second bank patterns BP1 and BP2 may have different widths in the second direction DR2. For example, one of the first and second bank patterns BP1 and BP2 may have a larger width than the other bank pattern and may be disposed across more than one subpixel SPXn adjacent to one another in the second direction DR2. In this example, whichever of the first and second bank patterns BP1 and BP2 may be wider than the other bank pattern may overlap part of the bank layer BNL that extends in the first direction DR1, in the thickness direction. Each of the subpixels SPXn is illustrated as having two bank patterns having the same width, but the disclosure is not limited thereto. The number and the shape of bank patterns provided in each of the subpixels SPXn may vary depending on the number and the layout of electrodes RME provided in each of the subpixels SPXn.

The electrodes RME may be disposed in each of the subpixels SPXn, extending in a direction. The electrodes RME may be disposed in the emission area EMA and the subarea SA of each of the subpixels SPXn, extending in the first direction DR1. The electrodes RME may be spaced apart from each other in the second direction DR2. The electrodes RME may be electrically connected to the light-emitting elements ED that will be described later, but the disclosure is not limited thereto. In other embodiments, the electrodes RME may not be electrically connected to the light-emitting elements ED.

The display device 10 may include, in each of the subpixels SPXn, first and second electrodes RME1 and RME2. The first electrode RME1 may be disposed on the left side of the center of the emission area EMA, and the second electrode RME2 may be spaced apart from the first electrode RME1 in the second direction DR2 and may be disposed on the right side of the center of the emission area EMA. The first electrode RME1 may be disposed on the first bank pattern BP1, and the second electrode RME2 may be disposed on the second bank pattern BP2. The first and second electrodes RME1 and RME2 may be disposed in part on the outside of the emission area EA and in the subarea SA, beyond the bank layer BNL. First electrodes RME1 or second electrodes RME2 from two different subpixels SPXn may be spaced apart from each other by a separation part ROP of a subarea SA of one of the two different subpixels SPXn.

FIG. 2 illustrates that two electrodes RME may be disposed in the first subpixel SPX1 to extend in the first direction DR1, but the disclosure is not limited thereto. In other embodiments, more than two electrodes RME may be disposed in each of the subpixels SPXn, or the electrodes RME may be bent in part and may have different widths from one location to another location.

The bank layer BNL may be disposed to surround each of the subpixels SPXn and the emission area EMA and the subarea SA of each of the subpixels SPXn. The bank layer BNL may be disposed not only along the boundaries between subpixels SPXn that may be adjacent to one another in the first or second direction DR1 or DR2, but also along the boundaries between emission areas EMA, between subareas SA, and between the emission areas EMA and the subareas SA. The subpixels SPXn, the emission areas EMA, and the subareas SA of the display device 10 may be areas defined by the bank layer BNL. The distances between the subpixels SPXn, the emission areas EMA, and the subareas SA of the display device 10 may vary depending on the width of the bank layer BNL

The bank layer BNL may include parts extending in the first direction DR1 and parts extending in the second direction DR2 and may be arranged in a lattice shape in a plan view, over the entire display area DPA. The bank layer BNL may be disposed along the boundaries of each of the subpixels SPXn to separate the subpixels SPXn from one another. The bank layer BNL may be disposed to surround and separate the emission area EMA and the subarea SA of each of the subpixels SPXn.

The light-emitting elements ED may be disposed in the emission area EMA of each of the subpixels SPXn. The light-emitting elements ED may be disposed between the bank patterns (BP1 and BP2) and may be spaced apart from one another in the first direction DR1. The light-emitting elements ED may extend in a direction, and both end portions of each of the light-emitting elements ED may be disposed on different electrodes RME. The length of the light-emitting elements ED may be greater than the distance, in the second direction DR2, of the electrodes RME. The light-emitting elements ED may be arranged in a direction perpendicular to the direction in which the electrodes RME extend, i.e., in a direction perpendicular to the first direction DR1, but the disclosure is not limited thereto. The direction in which the light-emitting elements SED extend may be the second direction DR2 or a direction inclined from the second direction DR2.

The connecting electrodes CNE may be disposed on the electrodes RME and the bank patterns (BP1 and BP2). The connecting electrodes CNE may extend in a direction and may be spaced apart from one another. The connecting electrodes CNE may be in contact with the light-emitting elements CNE and may be electrically connected to the electrodes RME or conductive layers therebelow.

The connecting electrodes CNE may include first and second connecting electrodes CNE1 and CNE2, which may be disposed in each of the subpixels SPXn. The first connecting electrode CNE1 may extend in the first direction DR1 and may be disposed on the first electrode RME1 or the first bank pattern BP1. The first connecting electrode CNE1 may partially overlap the first electrode RME1 and may be disposed not only in the emission area EMA of each of the subpixels SPXn, but also in the subarea SA of each of the subpixels SPXn, beyond the bank layer BNL. The second connecting electrode CNE2 may extend in the first direction DR1 and may be disposed on the second electrode RME2 or the second bank pattern BP2. The second connecting electrode CNE2 may partially overlap the second electrode RME2 and may be disposed not only in the emission area EMA of each of the subpixels SPXn, but also in the subarea SA of each of the subpixels SPXn, beyond the bank layer BNL.

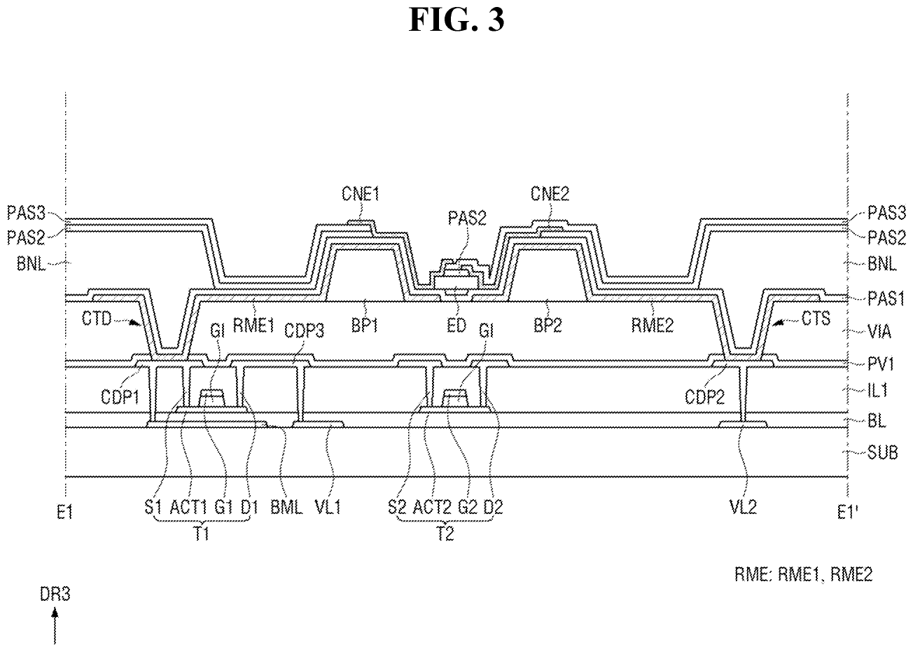

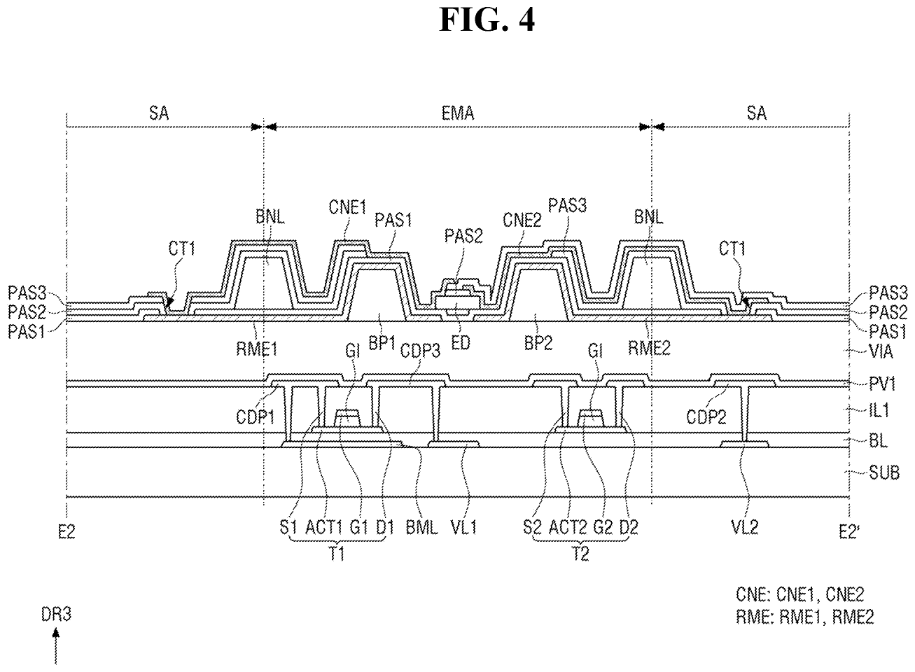

FIG. 3 is a schematic cross-sectional view taken along line E1-E1′ of FIG. 2. FIG. 4 is a schematic cross-sectional view taken along line E2-E2′ of FIG. 2. FIG. 3 illustrates a cross-sectional view taken across both end portions of a light-emitting element ED and first and second electrode contact holes CTD and CTS in the first subpixel SPX1 of FIG. 2, and FIG. 4 illustrates a cross-sectional view taken across both end portions of a light-emitting element ED and first and second contacts CT1 and CT2 of the first subpixel SPX1 of FIG. 2.

Referring to FIGS. 3 and 4 and further to FIG. 2, the display device 10 may include a first substrate SUB and a semiconductor layer, conductive layers, and insulating layers, which may be disposed on the first substrate SUB. The display device 10 may include, for example, in the first subpixel SPX1, electrodes RME, light-emitting elements ED, and connecting electrodes CNE. The semiconductor layer, the conductive layers, and the insulating layers may form a circuit layer of the display device 10.

The first substrate SUB may be an insulating substrate. The first substrate SUB may be formed of an insulating material such as glass, quartz, or a polymer resin. The first substrate SUB may be a rigid substrate or may be a flexible substrate that may be bendable, foldable, or rollable. The first substrate SUB may include a display area DPA and a non-display area NDA, which surrounds the display area DPA, and the display area DPA may include an emission area EMA and a subarea SA, which may be part of a non-emission area.

A first conductive layer may be disposed on the first substrate SUB. The first conductive layer may include a lower metal layer BML. The lower metal layer BML may be disposed to overlap a first active layer ACT1 of a first transistor T1. The lower metal layer BML may prevent light from being incident upon the first active layer ACT1 of the first transistor T1 or may be electrically connected to the first active layer ACT1 to stabilize the electrical characteristics of the first transistor T1. The lower metal layer BML may not be provided.

A high-potential voltage (or a first power supply voltage) to be delivered to a first electrode RME1 may be applied to a first voltage line VL1, and a low-potential voltage (or a second power supply voltage) to be delivered to a second electrode RME2 may be applied to a second voltage line VL2. The first voltage line VL1 may be electrically connected to the first transistor T1 through a conductive pattern of a third conductive layer, for example, a third conductive pattern CDP3. The second voltage line VL2 may be electrically connected to the second electrode RME2 through a conductive pattern of the third conductive layer, for example, a second conductive pattern CDP2.

The first and second voltage lines VL1 and VL2 may be illustrated as being disposed in the first conductive layer, but the disclosure is not limited thereto. In other embodiments, the first and second voltage lines VL1 and VL2 may be disposed in the third conductive layer and may thus be directly and electrically connected to the first transistor T1 and the second electrode RME2, respectively.

A buffer layer BL may be disposed on the lower metal layer BML and the first substrate SUB. The buffer layer BL may be formed on the first substrate SUB to protect the transistors of the first subpixel SPX1 from moisture that may penetrate through the first substrate SUB, which may be vulnerable to moisture, and may perform a surface planarization function.

The semiconductor layer may be disposed on the buffer layer BL. The semiconductor layer may include the first active layer ACT1 of the first transistor T1 and a second active layer ACT2 of a second transistor T2. The first and second active layers ACT1 and ACT2 may be disposed to partially overlap first and second gate electrodes G1 and G2, respectively, of a second conductive layer that will be described later.

The semiconductor layer may include polycrystalline silicon, monocrystalline silicon, or an oxide semiconductor. In other embodiments, the semiconductor layer may include polycrystalline silicon. The oxide semiconductor may be an oxide semiconductor containing indium (In). For example, the oxide semiconductor may be at least one of indium tin oxide (ITO), indium zinc oxide (IZO), indium gallium oxide (IGO), indium zin tin oxide (IZTO), indium gallium tin oxide (IGTO), and indium gallium zinc tin oxide (IGZTO).

FIGS. 3 and 4 illustrate that the first subpixel SPX1 includes two transistor, i.e., the first transistor T1 and the second transistor T2, but the disclosure is not limited thereto. For example, the first subpixel SPX1 may include more than two transistors.

The first gate insulating layer GI may be disposed on the semiconductor layer and the buffer layer BL, in the display area DPA. The first gate insulating layer GI may not be disposed in the pad area PDA. The first gate insulating layer GI may function as a gate insulating layer for first and second transistors T1 and T2 of the second conductive layer. As illustrated, the first gate insulating layer GI may be patterned together with first and second gate electrodes G1 and G2 of the second conductive layer that will be described later and may thus be placed in part between the second conductive layer and the first and second active layers ACT1 and ACT2 of the semiconductor layer, but the disclosure is not limited thereto. In other embodiments, the first gate insulating layer GI may be disposed on the entire surface of the buffer layer BL.

The second conductive layer may be disposed on the first gate insulating layer GI. The second conductive layer may include the first and second gate electrodes G1 and G2 of the first and second transistors T1 and T2. The first gate electrode G1 may be disposed to overlap the channel region of the first active layer ACT1 in a thickness direction, i.e., in the third direction DR3, and the second gate electrode G2 may be disposed to overlap the channel region of the second active layer ACT2 in the thickness direction, i.e., in the third direction DR3. Although not specifically illustrated, the second conductive layer may further include a first electrode of a storage capacitor.

The first interlayer insulating layer IL1 may be disposed on the second conductive layer. The first interlayer insulating layer IL1 may function as an insulating film between the second conductive layer and layers disposed on the second conductive layer and may protect the second conductive layer.

The third conductive layer may be disposed on the first interlayer insulating layer IL1. The third conductive layer may include the first through third conductive patterns CDP1 through CDP3, first and second source electrodes S1 and S2 of the first and second transistors T1 and T2 and first and second drain electrodes D1 and D2 of the first and second transistors T1 and T2. Some of the first through third conductive patterns CDP1 through CDP3 may electrically connect different conductive layers or semiconductor layers and may thus serve as the source and drain electrodes of each of the first and second transistors T1 and T2.

The first conductive pattern CDP1 may be in contact with the first active layer ACT1 of the first transistor T1 through a contact hole that penetrates the first interlayer insulating layer IL1 and the first gate insulating layer GI. Also, the first conductive pattern CDP1 may be in contact with the lower metal layer BML, through another contact hole. The first conductive pattern CDP1 may function as a first source electrode S1 of the first transistor T1. The first conductive pattern CDP1 may be connected to the first electrode RME1 or a first connecting electrode CNE1 that will be described later. The first transistor T1 may transmit the first power supply voltage from the first voltage line VL1 to the first electrode RME1 or the first connecting electrode CNE1.

The second conductive pattern CDP2 may be in contact with the second voltage line VL2 through a contact hole penetrating the first interlayer insulating layer IL1 and the buffer layer BL. The second conductive pattern CDP2 may be electrically connected to the first electrode RME1 or the first connecting electrode CNE1. The second voltage line VL2 may transmit the second power supply voltage to the second electrode RME2 or the second connecting electrode CNE2.

The third conductive pattern CDP3 may be in contact with the first voltage line VL1 through a contact hole penetrating the first interlayer insulating layer IL1 and the buffer layer BL. The third conductive pattern CDP3 may be electrically connected to the first active layer ACT1 of the first transistor Ti through a contact hole penetrating the first interlayer insulating layer ILL The third conductive pattern CDP3 may electrically connect the first voltage line VL1 and the first transistor T1 and may function as the first drain electrode D1 of the first transistor T1.

The second source electrode S2 and the second drain electrode D2 may be in contact with the second active layer ACT2 of the second transistor T2 through contact holes penetrating the first interlayer insulating layer ILL The second transistor T2 may transmit a data signal or an initialization signal to the first transistor T1.

The first passivation layer PV1 may be disposed on the third conductive layer. The first passivation layer PV1 may function as an insulating film between the third conductive layer and other layers and protect the third conductive layer.

Each of the buffer layer BL, the first gate insulating layer GI, the first interlayer insulating layer ILL and the first passivation layer PV1 may include inorganic layers that may be alternately stacked on each other. For example, each of the buffer layer BL, the first gate insulating layer GI, the first interlayer insulating layer ILL and the first passivation layer PV1 may be formed as a double- or multilayer in which inorganic layers of at least one of silicon oxide (SiOₓ), silicon nitride (SiNₓ), and silicon oxynitride (SiOₓN_{y}) may be alternately stacked on each other, but the disclosure is not limited thereto. In another example, each of the buffer layer BL, the first gate insulating layer GI, the first interlayer insulating layer ILL and the first passivation layer PV1 may be formed as a single inorganic layer including SiOₓ, SiNₓ, or SiOₓN_{y}. In some embodiments, the first interlayer insulating layer IL1 may be formed of an organic insulating material such as polyimide

A via layer VIA may be disposed on the third conductive layer, in the display area DPA. The via layer VIA may include an organic insulating material such as, for example, polyimide, and may perform a surface planarization function by compensating for any height differences generated by the underlying conductive layers. In some embodiments, the via layer VIA may not be provided.

The display device 10 may include, as a display element layer on the via layer VIA, the bank patterns (BP1 and BP2), the electrodes RME, the bank layer BNL, the light-emitting elements ED, and the connecting electrodes CNE. The display device 10 may include first through third insulating layers PAS1 through PAS3, which may be disposed on the via layer VIA.

The bank patterns (BP1 and BP2) may be disposed on the via layer VIA. For example, the bank patterns (BP1 and BP2) may be disposed directly on the via layer VIA and may protrude at least in part from the top surface of the via layer VIA. Each of protruding parts of the bank patterns (BP1 and BP2) may have inclined or bent sides with a curvature, and light emitted from the light-emitting elements ED may be reflected by the electrodes RME on the bank patterns (BP1 and BP2) to be emitted in an upward direction from the via layer VIA. In other embodiments, the bank patterns (BP1 and BP2) may have a bent shape with a curvature, for example, a semicircular or semielliptical shape, in a cross-sectional view. The bank patterns (BP1 and BP2) may include an inorganic insulating material such as polyimide, but the disclosure is not limited thereto.

The electrodes RME may be disposed on the bank patterns (BP1 and BP2) and the via layer VIA. For example, the electrodes RME may be disposed at least on inclined sides of the bank patterns (BP1 and BP2). The width, in the second direction DR2, of the electrodes RME may be less than the width, in the second direction DR2, of the bank patterns (BP1 and BP2), and the distance, in the second direction DR2, between the electrodes RME may be less than the distance, in the second direction DR2, between the bank patterns (BP1 and BP2). The first and second electrodes RME1 and RME2 may be disposed, at least in part, directly on the via layer VIA and may thus be placed on the same plane.

The light-emitting elements ED, which may be disposed between the bank patterns (BP1 and BP2), may emit light through both end portions thereof, and the emitted light may travel toward the electrodes RME on the bank patterns (BP1 and BP2). Parts of the electrodes RME that may be disposed on the bank patterns (BP1 and BP2) may have a structure capable of reflecting light emitted from the light-emitting elements ED. The first and second electrodes RME1 and RME2 may be disposed to cover at least sides of the bank patterns (BP1 and BP2) to reflect light emitted from the light-emitting elements ED.

The electrodes RME may be in direct contact with the third conductive layer through the first and second electrode contact holes CTD and CTS in an area where the electrodes RME overlap the bank layer BNL, between the emission area EMA and the subarea SA. The first electrode contact hole CTD may be formed in a region where the bank layer BNL and the first electrode RME1 overlap each other, and the second electrode contact hole CTS may be formed in a region where the bank layer BNL and the second electrode RME2 overlap each other. The first electrode RME1 may be in contact with the first conductive pattern CDP1 through the first electrode contact hole CTD, which penetrates the via layer VIA and the first passivation layer PV1. The second electrode RME2 may be in contact with the second voltage line VL2 through the second electrode contact hole CTS, which penetrates the via layer VIA and the first passivation layer PV1. The first electrode RME1 may be electrically connected to the first transistor Ti through the first conductive pattern CDP1 and may thus receive the first power supply voltage, and the second electrode RME2 may be electrically connected to the second voltage line VL2 and may thus receive the second power supply voltage. However, the disclosure is not limited to this. In other embodiments, the electrodes RME may not be electrically connected to the first and second voltage lines VL1 and VL2 of the third conductive layer and may be directly connected to the third conductive layer.

The electrodes RME may include a conductive material with high reflectance. For example, the electrodes RME may include a metal such as silver (Ag), copper (Cu), or aluminum (Al), an alloy including Al, nickel (Ni), or lanthanum (La), or a stack of a layer of such alloy and a layer of a metal such as titanium (Ti), molybdenum (Mo), or niobium (Nb). In some embodiments, the electrodes RME may be formed as double- or multilayers in which at least one layer of an alloy containing Al and at least one layer of a metal such as Ti, Mo, or Nb may be stacked on each other.

However, the disclosure is not limited to this. In other embodiments, the electrodes RME may further include a transparent conductive material. For example, the electrodes RME may include a material such as ITO, IZO, or IZTO. In some embodiments, the electrodes RME may have a structure in which at least one layer of a transparent conductive material and at least one layer of a metal with high reflectance may be stacked on each other or may be formed as single-layer films including the transparent conductive material and the metal with high reflectance. For example, the electrodes RME may have a stack structure such as ITO/Ag/ITO/, ITO/Ag/IZO, or ITO/Ag/IZTO/IZO. The electrodes RME may be electrically connected to the light-emitting elements ED and may reflect light (e.g., some light), emitted from the light-emitting elements ED, in an upward direction from the first substrate SUB.

The first insulating layer PAS1 may be disposed in the entire display area DPA, on the via layer VIA and the electrodes RME. The first insulating layer PAS1 may include an insulating material and may thus be able to protect the electrodes RME and to insulate the electrodes RME from each other. As the first insulating layer PAS1 may be disposed to cover the electrodes RME, before the formation of the bank layer BNL, the first insulating layer PAS1 can prevent the electrodes RME from being damaged during the formation of the bank layer BNL. Also, the first insulating layer PAS1 can prevent the light-emitting elements ED from being in direct contact with, and damaged by, other members.

The first insulating layer PAS1 may be formed to be recessed in part between the electrodes RME, which may be spaced apart from each other in the second direction DR2. The light-emitting elements ED may be disposed on the top surface of a recessed part of the first insulating layer PAS1, and space may be formed between the light-emitting elements ED and the first insulating layer PAS1.

The first insulating layer PAS1 may include first and second contacts CT1 and CT2, which may be disposed in the subarea SA. The first and second contacts CT1 and CT2 may be disposed to overlap different electrodes. For example, the first contact CT1 may be disposed to overlap the first electrode RME1, and the second contact CT2 may be disposed to overlap the second electrode RME2. The first and second contacts CT1 and CT2 may expose parts of the top surfaces of the first and second electrodes RME1 and RME2 through the first insulating layer PAS1. The first and second contacts CT1 and CT2 may further penetrate other insulating layers on the first insulating layer PAS1. Parts of the electrodes RME that may be exposed by the first and second contacts CT1 and CT2 may be in contact with the connecting electrodes CNE.

The bank layer BNL may be disposed on the first insulating layer PAS1. The bank layer BNL may include parts extending in the first direction DR1 and parts extending in the second direction DR2 and may surround the first subpixel SPX1. The bank layer BNL may be disposed along the boundaries of the display area DPA to separate the display area DPA and the non-display area NDA.

The bank layer BNL, like the bank patterns (BP1 and BP2), may have a height. In some embodiments, the height of the bank layer BNL may be greater than the height of the bank patterns (BP1 and BP2), and the thickness of the bank layer BNL may be the same as, or greater than, the thickness of the bank patterns (BP1 and BP2). The bank layer BNL may prevent ink from spilling into neighboring subpixels SPXn in an inkjet printing process as performed during the fabrication of the display device 10. The bank layer BNL, like the bank patterns (BP1 and BP2), may include an organic insulating material such as polyimide.

The light-emitting elements ED may be disposed in the emission area EMA of the first subpixel SPX1. The light-emitting elements ED may be disposed on the first insulating layer PAS1, between the bank patterns (BP1 and BP2). The direction in which the light-emitting elements ED extend may be parallel to the top surface of the first substrate SUB. As will be described later, each of the light-emitting elements ED may include multiple semiconductor layers that may be arranged in the direction in which the light-emitting elements ED extend, and the multiple semiconductor layers may be sequentially arranged in a direction parallel to the top surface of the first substrate SUB. However, the disclosure is not limited to this configuration. In other embodiments, the multiple semiconductor layers may be arranged in a direction perpendicular to the first substrate SUB.

The light-emitting elements ED of one subpixel SPXn may emit light of a different wavelength range from the light-emitting elements ED of another subpixel SPXn, depending on the materials of the semiconductor layers of each of the light-emitting elements ED of each subpixel SPXn, but the disclosure is not limited thereto. In other embodiments, the semiconductor layers of each of the light-emitting elements ED of one subpixel SPXn may include the same materials as the semiconductor layers of each of the light-emitting elements ED of another subpixel SPXn, so that the light-emitting elements ED of one subpixel SPXn may emit light of the same color as the light-emitting elements ED of another subpixel SPXn.

The light-emitting elements ED may be in contact with the connecting electrodes CNE to be electrically connected to the light-emitting elements RME and the conductive layers below the via layer VIA and may emit light of a particular wavelength range in response to electrical signals being applied thereto.

The second insulating layer PAS2 may be disposed on the light-emitting elements ED, the first insulating layer PAS1, and the bank layer BNL. The second insulating layer PAS2 may include pattern parts, which extend in the first direction DR1 between the bank patterns (BP1 and BP2) and may be disposed on the light-emitting elements ED. The pattern parts may be disposed to surround the outer surfaces of each of the light-emitting elements ED, but not to cover both sides or both end portions of each of the light-emitting elements ED. The pattern parts may form linear or island patterns in the first subpixel SPX1 in a plan view. The pattern parts of the second insulating layer PAS2 may protect the light-emitting elements ED and may fix the light-emitting elements ED during the fabrication of the display device 10. The second insulating layer PAS2 may be disposed to fill the space between the first insulating layer PAS1 and the light-emitting elements ED. Parts of the second insulating layer PAS2 may be disposed on the bank layer BNL and in the subarea SA.

The second insulating layer PAS2 may include the first and second contacts CT1 and CT2, which may be disposed in the subarea SA. The second insulating layer PAS2 may include the first and second contacts CT1 and CT2, which may be disposed to overlap the first and second electrodes RME1 and RME2, respectively. The first and second contacts CT1 and CT2 may penetrate not only the first insulating layer PAS1, but also the second insulating layer PAS2. The first and second contacts CT1 and CT2 may expose parts of the top surfaces of the first and second electrodes RME1 and RME2, respectively.

The connecting electrodes CNE may be disposed on the electrodes RME and the bank patterns (BP1 and BP2). The first connecting electrode CNE1 may be disposed on the first electrode RME1 and the first bank pattern BP1. The first connecting electrode CNE1 may partially overlap the first electrode RME1 and may be disposed not only in the emission area EMA, but also in the subarea SA, beyond the bank layer BNL. The second connecting electrode CNE2 may be disposed on the second electrode RME2 and the second bank pattern BP2. The second connecting electrode CNE2 may partially overlap the second electrode RME2 and may be disposed not only in the emission area EMA, but also in the subarea SA, beyond the bank layer BNL.

The first and second connecting electrodes CNE1 and CNE2 may be disposed on the second insulating layer PAS2 and may be in contact with the light-emitting elements ED. The first connecting electrode CNE1 may partially overlap the first electrode RME1 and may be in contact with first end portions of the light-emitting elements ED. The second connecting electrode CNE2 may partially overlap the second electrode RME2 and may be in contact with second end portions of the light-emitting elements ED. The connecting electrodes CNE may be disposed not only in the emission area EMA, but also in the subarea SA beyond the emission area EMA. The connecting electrodes CNE may be in contact with the light-emitting elements ED, in the emission area EMA, and may be electrically connected to the third conductive layer, in the subarea SA. The first connecting electrode CNE1 may be in contact with the first end portions of the light-emitting elements ED, and the second connecting electrode CNE2 may be in contact with the second end portions of the light-emitting elements ED.

The connecting electrodes CNE may be in contact with the electrodes RME through the first and second contacts CT1 and CT2, which may be disposed in the subarea SA. The first connecting electrode CNE1 may be in contact with the first electrode RME1 through the first contact CT1, which penetrates the first through third insulating layers PAS1 through PAS3, in the subarea SA. The second connecting electrode CNE2 may be in contact with the second electrode RME2 through the second contact CT2, which penetrates the first and second insulating layers PAS1 and PAS2, in the subarea SA. The connecting electrodes CNE may be electrically connected to the third conductive layer through the electrodes RME. The first connecting electrode CNE1 may be electrically connected to the first transistor T1 to receive the first power supply voltage, and the second connecting electrode CNE2 may be electrically connected to the second voltage line VL2 to receive the second power supply voltage. The connecting electrodes CNE may be in contact with the light-emitting elements ED, in the emission area EMA, to transmit power supply voltages to the light-emitting elements ED.

However, the disclosure is not limited to this. In other embodiments, the connecting electrodes CNE may be in direct contact with the third conductive layer or may be electrically connected to the third conductive layer not through the electrodes RME, but through other patterns.

The connecting electrodes CNE may include a conductive material. For example, the connecting electrodes CNE may include ITO, IZO, IZTO, or Al. For example, the connecting electrodes CNE may include a transparent conductive material so that light emitted by the light-emitting elements ED may be output through the connecting electrodes CNE.

The third insulating layer PAS3 may be disposed on the second connecting electrode CNE2 and the second insulating layer PAS2 of a first connecting electrode layer. The third insulating layer PAS3 may be disposed on the entire surface of the second insulating layer PAS2 to cover the second connecting electrode CNE2, and the first connecting electrode CNE1 of a second connecting electrode layer may be disposed on the third insulating layer PAS3. The third insulating layer PAS3 may insulate the first and second connecting electrodes CNE1 and CNE2 from each other so that the first and second connecting electrodes CNE1 and CNE2 may not be in direct contact with each other.

The third insulating layer PAS3 may include the first contact CT1, which may be disposed in the subarea SA. The first contact CT1 may penetrate not only the first and second insulating layers PAS1 and PAS2, but also the third insulating layer PAS3. The first contact CT1 may expose part of the top surface of the first electrode RME1.

Although not specifically illustrated, another insulating layer may be further disposed on the third insulating layer PAS3 and the first connecting electrode CNE1. The insulating layer may protect the members disposed on the first substrate SUB from an external environment.

The first through third insulating layers PAS1 through PAS3 may include an inorganic insulating material or an organic insulating material. For example, the first through third insulating layers PAS1 through PAS3 may all include an inorganic insulating material. In another example, the first and third insulating layers PAS1 and PAS3 may include an inorganic insulating material, and the second insulating layer PAS2 may include an organic insulating material. At least one of the first through third insulating layers PAS1 through PAS3 may have a structure in which multiple insulating layers may be alternately or repeatedly stacked on each other. The first through third insulating layers PAS1 through PAS3 may include at least one of SiOₓ, SiNₓ, or SiOₓN_{y}. The first through third insulating layers PAS1 through PAS3 may include the same material, some of the first through third insulating layers PAS1 through PAS3 may include the same material, or the first through third insulating layers PAS1 through PAS3 may include different materials.

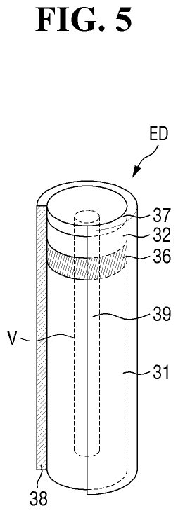

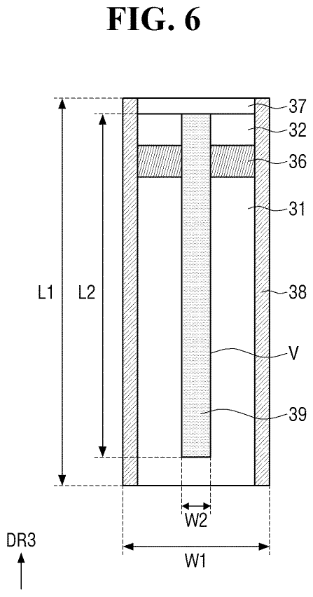

FIG. 5 is a schematic perspective view of a light-emitting element according to an embodiment of the disclosure. FIG. 6 is a schematic cross-sectional view of the light-emitting element of FIG. 5.

Referring to FIGS. 5 and 6, a light-emitting element ED may be an LED. Specifically, the light-emitting element ED may be an ILED having a size of several nanometers or micrometers and formed of an inorganic material. If an electric field is formed in a particular direction between two opposite electrodes, the light-emitting element ED may be aligned between the two electrodes where polarities may be formed.

The light-emitting element ED may have a shape that extends in a direction. The light-emitting element ED may have the shape of a cylinder, a rod, a wire, or a tube, but the shape of the light-emitting element ED is not particularly limited. In other embodiments, the light-emitting element ED may have the shape of a polygonal column such as a regular cube, a rectangular parallelepiped, or a hexagonal column or may have a shape that extends in a direction but with a partially inclined outer surface.

The light-emitting element ED may include semiconductor layers doped with a dopant of an arbitrary conductivity type (e.g., a p type or an n type). The semiconductor layers may receive electric signals from an external power source to emit light of a particular wavelength range. The light-emitting element ED may include a first semiconductor layer 31, a second semiconductor layer 32, the light-emitting layer 36, an electrode layer 37, and the insulating film 38.

The first semiconductor layer 31 may include an n-type semiconductor. The first semiconductor layer 31 may include a semiconductor material, i.e., AlₓGa_{y}In_{1-x-y}N (where 0≤x≤1,0≤y≤1, and 0≤x+y≤1). For example, the first semiconductor layer 31 may include at least one of AlGaInN, GaN, AlGaN, InGaN, AlN, and InN that may be doped with an n-type dopant. The n-type dopant may be silicon (Si), germanium (Ge), tin (Sn), or selenium (Se).

The second semiconductor layer 32 may be disposed on the first semiconductor layer 31 with the light-emitting layer 36 interposed therebetween. The second semiconductor layer 32 may include a p-type semiconductor. The second semiconductor layer 32 may include a semiconductor material, i.e., AlₓGa_{y}In_{1-x-y}N (where 0≤x≤1,0≤y≤1, and 0≤x+y≤1). For example, the second semiconductor layer 32 may include at least one of AlGaInN, GaN, AlGaN, InGaN, AlN, and InN that may be doped with a p-type dopant. The p-type dopant may be Mg, Zn, Ca, or Ba.

FIGS. 5 and 6 illustrate that the first and second semiconductor layers 31 and 32 may be formed as single layers, but the disclosure is not limited thereto. In other embodiments, each of the first and second semiconductor layers 31 and 32 may include more than one layer such as, for example, a clad layer or a tensile strain barrier reducing (TSBR) layer, depending on the material of the light-emitting layer 36. For example, the light-emitting element ED may further include a semiconductor layer between the first semiconductor layer 31 and the light-emitting layer 36 or a semiconductor layer between the second semiconductor layer 32 and the light-emitting layer 36. The semiconductor layer between the first semiconductor layer 31 and the light-emitting layer 36 may include at least one of AlGaInN, GaN, AlGaN, InGaN, AlN, InN, and SLs that may be doped with an n-type dopant, and the semiconductor layer between the second semiconductor layer 32 and the light-emitting layer 36 may include at least one of AlGaInN, GaN, AlGaN, InGaN, AlN, and InN that may be doped with a p-type dopant.

The light-emitting layer 36 may be disposed between the first and second semiconductor layers 31 and 32. The light-emitting layer 36 may include a single- or multi-quantum well structure material. In a case where the light-emitting layer 36 includes a material having a multi-quantum well structure, the light-emitting layer 36 may have a structure in which multiple quantum layers and multiple well layers may be alternately stacked on each other. The light-emitting layer 36 may emit light by combining electron-hole pairs in accordance with electric signals applied thereto via the first and second semiconductor layers 31 and 32. The light-emitting layer 36 may include a material such as AlGaN, AlGaInN, or InGaN. In particular, in a case where the light-emitting layer 36 has a multi-quantum well structure in which multiple quantum layers and multiple well layers may be alternately stacked on each other, the quantum layers may include a material such as AlGaN or AlGaInN, and the well layers may include a material such as GaN, InGaN, or AlInN.

The light-emitting layer 36 may have a structure in which a semiconductor material having a large band gap energy and a semiconductor material having a small band gap energy may be alternately stacked on each other or may include group-III or group-V semiconductor materials depending on the wavelength of light to be emitted. The type of light emitted by the light-emitting layer 36 is not particularly limited. The light-emitting layer 36 may emit light of a red or green wavelength range as necessary, instead of blue light.

The electrode layer 37 may be an ohmic connecting electrode, but the disclosure is not limited thereto. In other embodiments, the electrode layer 37 may be a Schottky connecting electrode. The light-emitting element ED may include at least one electrode layer 37. The light-emitting element ED may include more than one electrode layer 37, but the disclosure is not limited thereto. In other embodiments, the electrode layer 37 may not be provided.

The electrode layer 37 may reduce the resistance between the light-emitting element ED and electrodes RME or (connecting electrodes CNE) in case that the light-emitting element ED is electrically connected to the electrodes RME or (the connecting electrodes CNE). The electrode layer 37 may include a conductive metal. For example, the electrode layer 37 may include at least one of Al, Ti, In, gold (Au), Ag, ITO, IZO, and IZTO.

The insulating film 38 may be disposed to surround the first and second semiconductor layers 31 and 32 and the electrode layer 37. For example, the insulating film 38 may be disposed to surround at least the light-emitting layer 36, but to expose both end portions, in the length direction, of the light-emitting element ED. The insulating film 38 may be formed to be rounded in a cross-sectional view, in a region adjacent to at least one end of the light-emitting element ED.

The insulating film 38 may include a material with insulating properties such as, for example, SiOₓ, SiNₓ, SiOₓN_{y}, aluminum nitride (AlNₓ), aluminum oxide (AlOₓ), zirconium oxide (ZrOₓ), hafnium oxide (HfOₓ), and titanium oxide (TiOₓ). The insulating film 38 may be illustrated as being a single-layer film, but the disclosure is not limited thereto. In other embodiments, the insulating film 38 may be formed as a multilayer film in which multiple layers may be stacked on each other.

The insulating film 38 may protect the first and second semiconductor layers 31 and 32 and the electrode layer 37. The insulating film 38 can prevent a short circuit that may occur in the light-emitting element 36 in case that the light-emitting element ED is in direct contact with electrodes to which electric signals may be applied. Also, the insulating film 38 can prevent the degradation of the emission efficiency of the light-emitting element ED.

The outer surface of the insulating film 38 may be subjected to surface treatment. The light-emitting element ED may be sprayed on electrodes while being dispersed in ink. Here, the surface of the insulating film 38 may be hydrophobically or hydrophilically treated to keep the light-emitting element ED dispersed in ink without agglomerating with other neighboring light-emitting elements ED.

The light-emitting element ED may include a void V, which may be formed inside the light-emitting element ED, and a filler layer 39, which fills the void V. The void V of the light-emitting element ED may be formed in at least some of the first and second semiconductor layers 31 and 32 and the light-emitting layer 36 and may be formed by removing parts of at least some of the first and second semiconductor layers 31 and 32 and the light-emitting layer 36. For example, the void V may be formed to penetrate the light-emitting layer 36 and the second semiconductor layer 32, but not the first semiconductor layer 31 entirely. As illustrated in FIGS. 5 and 6, the void V may extend in the length direction of the light-emitting element ED and may be formed across the first semiconductor layer 31, the light-emitting layer 36, and the second semiconductor layer 32, but the disclosure is not limited thereto. In other embodiments, the void V of the light-emitting element ED may be formed to penetrate only some of the first semiconductor layer 31, the light-emitting layer 36, and the second semiconductor layer 32 or may be formed in only one of the first semiconductor layer 31, the light-emitting layer 36, and the second semiconductor layer 32.

The void V may be illustrated as extending in the middle of the light-emitting element ED, along the length direction of the light-emitting element ED, but the disclosure is not limited thereto. For example, the void V may be formed not in the middle of the light-emitting element ED, but near the outer side of the light-emitting element ED. In an embodiment, the void V may be positioned in the middle of the light-emitting element ED.

As will be described later, the first and second semiconductor layers 31 and 32 and the light-emitting layer 36 of the light-emitting element ED may be formed by epitaxial growth. The void V may be formed by a separate process of etching parts of the first and second semiconductor layers 31 and 32 and the light-emitting layer 36. The void V may be formed by a separate etching process for forming the void V, rather than by failure to properly deposit the materials of the first and second semiconductor layers 31 and 32 and the light-emitting layer 36. The location of the void V may vary depending on how the separate etching process proceeds.

The void may extend in the length direction of the light-emitting element ED. The light-emitting element ED may be obtained by forming the first and second semiconductor layers 31 and 32 and the light-emitting layer 36 through epitaxial growth and etching the first and second semiconductor layers 31 and 32 and the light-emitting layer 36 along the length direction of the light-emitting element ED. As the light-emitting element ED may be obtained by etching the first and second semiconductor layers 31 and 32 and the light-emitting layer 36 in a direction, the light-emitting element ED may have a shape extending in a direction. As will be described later, a process of forming a hole in each of the first and second semiconductor layers 31 and 32 and the light-emitting layer 36 may be performed in the same direction as an etching process for forming the light-emitting element ED. The hole formed in each of the first and second semiconductor layers 31 and 32 and the light-emitting layer 36 may become the void V. Accordingly, the light-emitting element ED may include the void V, which extends in the same direction as the light-emitting element ED. This will be described later in further detail.

The void V may be formed not to completely penetrate the first semiconductor layer 31 and the electrode layer 37. For example, a length L1 of the light-emitting element ED may be greater than a length L2 of the void V, and the length L2 of the void V may be less than the sum of the thicknesses of the first semiconductor layer 31, the light-emitting layer 36, and the second semiconductor layer 32. In an embodiment where the void V may not be formed in the second semiconductor layer 32 and the light-emitting layer 36, the length L2 of the void V may be less than the thickness of the first semiconductor layer 31. As the process for forming the void V may be formed after the formation of the first and second semiconductor layers 31 and 32 and the light-emitting layer 36, the void V may not be formed in the electrode layer 37, which may be disposed on the second semiconductor layer 32, if the void V does not completely penetrate the light-emitting element ED.

A diameter W2 of the void V may be set in consideration of a diameter W1 of the light-emitting element ED without impairing the optical characteristics of the light-emitting element ED. If the diameter W2 of the void V may be too large, the void V may account for too much of the light-emitting element ED, and thus, the light-emitting element ED may not be able to have a sufficient optical efficiency. Particularly, in an embodiment where the void V may be formed to penetrate the light-emitting layer 36, the optical characteristics and the emission wavelength of the light-emitting layer 36 may change because of part of the light-emitting element 36 being etched away. The diameter W2 of the void V may be less than 50% of the diameter W1 of the light-emitting element ED, but the disclosure is not limited thereto.

The filler layer 39 may be disposed in the void V of the light-emitting element ED. The filler layer 39 may completely fill the void V and may be in contact with the first and second semiconductor layers 31 and 32 and the light-emitting layer 36, depending on the location of the void V. For example, in an embodiment where the void V may be formed through the light-emitting layer 36 and the second semiconductor layer 32 to penetrate only part of the first semiconductor layer 31, the filler layer 39 may be in contact with the inner sides of the first semiconductor layer 31, the light-emitting layer 37, and the second semiconductor layer 32 that meet the void V, but the disclosure is not limited thereto. The filler layer 39 may be surrounded by the first semiconductor layer 31, the light-emitting layer 36, and the second semiconductor layer 32. In an embodiment where the void V may be formed to reach the bottom surface of the electrode layer 37, the top surface of the filler layer 39 may be in contact with the bottom surface of the electrode layer 37, but the disclosure is not limited thereto. The layer(s) that the filler layer 39 may be in contact with may vary depending on the location of the void V.

The filler layer 39 may include an insulating material having a lower specific gravity than the first and second semiconductor layers 31 and 32 and the light-emitting layer 36. As the filler layer 39 may be in contact with the first and second semiconductor layers 31 and 32 depending on the location of the void V, the filler layer 39 may include an insulating material to prevent the first and second semiconductor layers 31 and 32 from being short-circuited. For example, the filler layer 39 may include an organic insulating material having a lower specific gravity than the first and second semiconductor layers 31 and 32, such as polyimide. The filler layer 39, unlike the insulating film 38, may include a flexible organic insulating material to fill the void V in the light-emitting element ED, but the disclosure is not limited thereto.

As the light-emitting element ED includes the first and second semiconductor layers 31 and 32 and the light-emitting layer 36, which have a high specific gravity, and also includes the void V and the filler layer 39, which fills the void V, the light-emitting element ED may have a smaller weight for its volume.

The light-emitting element ED may be disposed to have both end portions placed on first and second electrodes RME1 and RME2. The light-emitting element ED may be sprayed onto the first and second electrodes RME1 and RME2 through printing, while being in a state of being dispersed in ink. While the locations of both end portions of the light-emitting element ED continue to change due to an electric field formed on the first and second electrodes RME1 and RME2, the light-emitting element ED may be settled on the first and second electrodes RME1 and RME2. If the light-emitting element ED contains a semiconductor material and has a high specific gravity, there may be insufficient time for both end portions of the light-emitting element ED to be properly aligned while floating in the ink. However, as the light-emitting element ED includes the void V and the filler layer 39 and has a relatively low specific gravity, there may be sufficient time for both end portions of the light-emitting element ED to be properly aligned while floating in the ink. As a result, the degree of alignment of light-emitting elements ED in the display device 10 may be improved, and the number of light-emitting elements ED that may be properly aligned per unit pixel PX may increase. Accordingly, product quality and process efficiency can be improved.

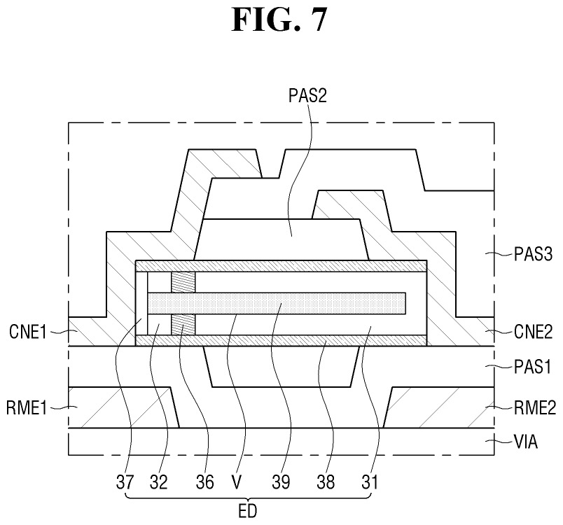

FIG. 7 is a schematic cross-sectional view illustrating an area in the display device of FIG. 2 where a light-emitting element may be disposed.

Referring to FIG. 7, a first end portion of a light-emitting element ED where an electrode layer 37 may be disposed may be disposed on a first electrode RME1, and a second end portion of the light-emitting element ED where a first semiconductor layer 31 may be disposed may be disposed on a second electrode RME2. The light-emitting element ED may include a void V, which extends in the length direction of the light-emitting element ED, and a filler layer 39, which fills the void V, and may also include the first semiconductor layer 31, a second semiconductor layer 32, a light-emitting layer 36, and the electrode layer 37, which may be sequentially arranged along the length direction of the light-emitting element ED. The first and second electrodes RME1 and RME2 may be disposed to be spaced apart from each other in the second direction DR2, and the first and second semiconductor layer 31 and 32, the light-emitting layer 36, and the electrode layer 37 of the light-emitting element ED may be arranged along the length direction of the light-emitting element ED. The light-emitting element ED may be arranged to extend in the second direction DR2, and the void V and the filler layer 39 may also be disposed to extend in the second direction DR2. In other embodiments, if the light-emitting element ED may be arranged to extend in the first direction DR1, the void V and the filler layer 39 may be disposed to extend in the first direction DR1.

A method of fabricating a light-emitting element ED will hereinafter be described.

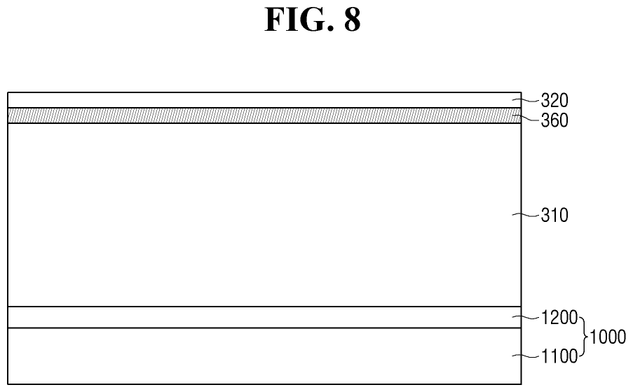

FIGS. 8 through 19 are schematic cross-sectional views illustrating a method of fabricating a light-emitting element according to an embodiment of the disclosure. FIGS. 8 through 19 sequentially illustrate how to fabricate light-emitting elements ED.

Referring to FIG. 8, a base substrate 1000 may be prepared, and a first semiconductor material layer 310, a light-emitting material layer 360, and a second semiconductor material layer 320 may be sequentially formed on the base substrate 1000.

The base substrate 1000 may include a lower substrate 1100 and a buffer material layer 1200, which may be disposed on the lower substrate 1100. The lower substrate 1100 may include a transparent substrate such as a sapphire (Al₂O₃) substrate or a glass substrate, but the disclosure is not limited thereto. In other embodiments, the lower substrate 1100 may be a conductive substrate formed of, for example, GaN, SiC, ZnO, Si, GaP, or GaAs. The thickness of the conductive substrate 1100 is not particularly limited. For example, the lower substrate 1100 may have a thickness of 400 μm to 1500 μm.

The buffer material layer 1200 may be provided to reduce the difference in lattice constant between the first semiconductor material layer 310 and the lower substrate 1100.

For example, the buffer material layer 1200 may include an undoped semiconductor. The buffer material layer 1200 may include substantially the same material as the first semiconductor material layer 310, such as a material not doped with an n- or p-type dopant, and may have a lower doping concentration than the first semiconductor material layer 310. For example, the buffer material layer 1200 may include at least one of InAlGaN, GaN, AlGaN, InGaN, AlN, and InN, but the disclosure is not limited thereto.

Semiconductor material layers may be formed on the base substrate 1000. The semiconductor material layers may be formed by growing seed crystals through epitaxial growth. Here, the semiconductor material layers may be formed by electron beam deposition, physical vapor deposition (PVD), chemical vapor deposition (CVD), plasma laser deposition (PLD), dual-type thermal evaporation, sputtering, or metal organic chemical vapor deposition (MOCVD), but the disclosure is not limited thereto.

A precursor material for forming the semiconductor material layers is not particularly limited. For example, the precursor material may include a metal precursor including an alkyl group such as a methyl group or an ethyl group. For example, in an embodiment where a first semiconductor layer 31, a second semiconductor layer 32, and a light-emitting layer 36 of each light-emitting element ED include at least one of AlGaInN, GaN, AlGaN, InGaN, AlN, and InN, the metal precursor may be a compound such as trimethyl gallium (Ga(CH₃)₃), trimethyl aluminum (Al(CH₃)₃), or triethyl phosphate ((C₂H₅)₃PO₄), but the disclosure is not limited thereto. The semiconductor material layers may be formed by a deposition process using the metal precursor and a non-metal precursor. Descriptions of how to, and under what conditions, to form the semiconductor material layers will be omitted, and instead, an order in which to fabricate light-emitting elements ED will hereinafter be described.

The first semiconductor material layer 310, the light-emitting material layer 360, and the second semiconductor material layer 320 may be formed on the base substrate 1000. The first semiconductor material layer 310, the light-emitting material layer 360, and the second semiconductor material layer 320 may correspond to first semiconductor layers 31, light-emitting layers 36, and second semiconductor layers 32, respectively, of light-emitting elements ED to be formed. For example, the first semiconductor material layer 310, the light-emitting material layer 360, and the second semiconductor material layer 320 may include the same materials as the first semiconductor layers 31, the light-emitting layers 36, and the second semiconductor layers 32, respectively, of the light-emitting elements ED.

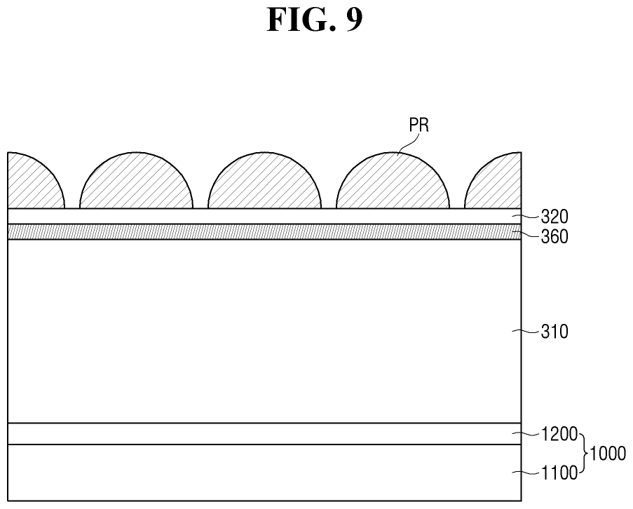

Thereafter, referring to FIGS. 9 through 11, first holes h1 may be formed by etching parts of the first and second semiconductor material layers 310 and 320 and the light-emitting material layer 360 on the base substrate 1000. The formation of the first holes h1 may include forming photoresist layers PR on the second semiconductor material layer 320 and etching parts where the photoresist layers PR may not be disposed, in a direction perpendicular to the top surface of the base substrate 1000.

Specifically, referring to FIG. 9, photoresist layers PR may be formed on the second semiconductor material layer 320 to be spaced apart from one another. The photoresist layers PR may be used as mask layers for etching the first and second semiconductor material layers 310 and 320 and the light-emitting material layer 360. The photoresist layers PR may be disposed on the second semiconductor material layer 320 to expose parts of the second semiconductor material layer 320 where the first holes h1 may be formed.

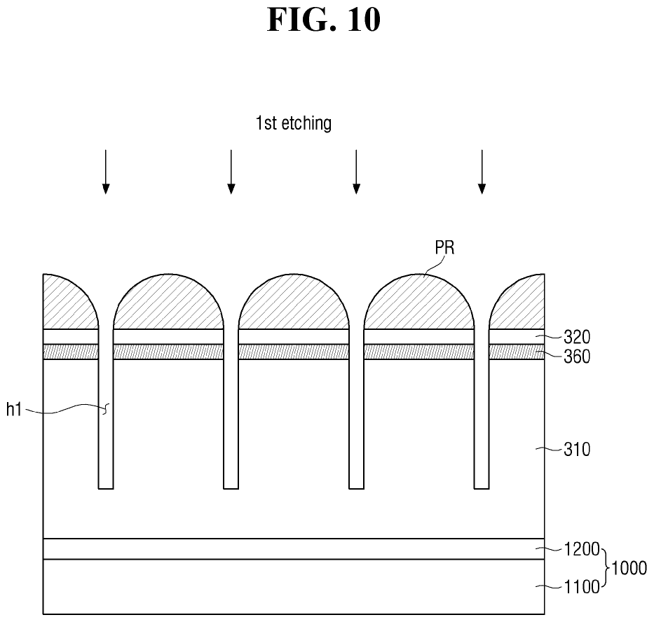

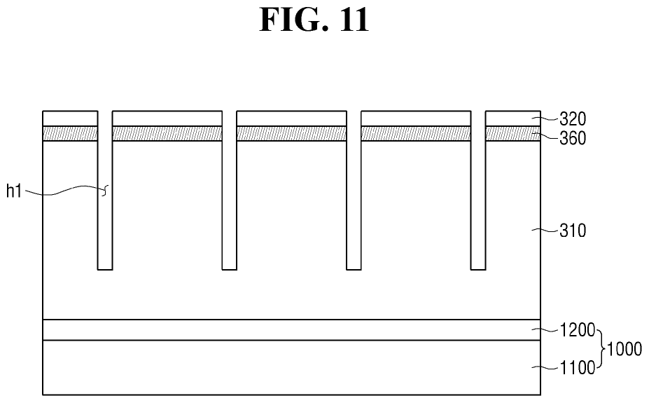

Thereafter, referring to FIGS. 10 and 11, the photoresist layers PR may be removed by performing a first etching process (“1^{st} etching”), which etches parts of the second semiconductor material layer 320 that may be exposed by the photoresist layer PR, in a direction perpendicular to the top surface of the base substrate 1000. The first etching process may be performed as a dry etching process or a wet etching process. The depth of the first holes h1 formed by the first etching process may vary depending on a set of conditions for the first etching process. The first holes h1 may be illustrated as penetrating the second semiconductor material layer 320 and the light-emitting material layer 360, but not a lower part of the first semiconductor material layer 310, but the disclosure is not limited thereto. The first holes h1 may become voids V, which may be formed in the light-emitting elements ED. The distance between the photoresist layers PR may be designed to be less than the diameter of the light-emitting elements ED. The first holes h1 may be formed to penetrate the second semiconductor material layer 320 and the light-emitting material layer 360, but not the first semiconductor material layer 310 entirely, and the light-emitting elements ED may be longer than the voids V.

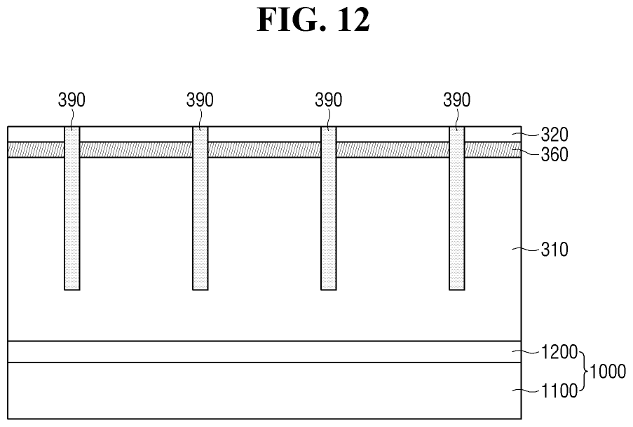

Thereafter, referring to FIG. 12, a filler material layer 390 may be disposed in the first holes h1 to fill the first holes h1, which may be formed in the first and second semiconductor material layers 310 and 320 and the light-emitting material layer 360. The filler material layer 390 may include an insulating material having a lower specific gravity than the first and second semiconductor material layers 310 and 320 and the light-emitting material layer 360. The filler material layer 390 may correspond to filler layers 39, which may be formed in the voids V of the light-emitting elements ED. As the first holes h1, which may be formed by etching the first and second semiconductor material layers 310 and 320 and the light-emitting material layer 360, may be filled with the filler material layer 390, layers can be stably disposed above the first holes h1.

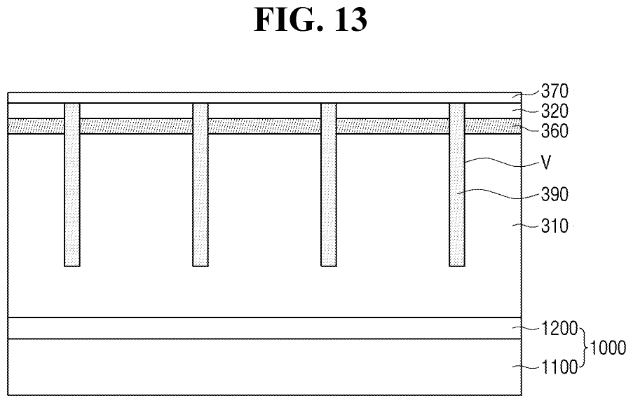

Thereafter, referring to FIG. 13, an electrode material layer 370 may be formed on the second semiconductor material layer 320 and the filler material layer 390. The electrode material layer 370, which corresponds to electrode layers 37 of the light-emitting elements ED, may include the same material as the electrode layers 37. The formation of the electrode material layer 370 is as already described above.

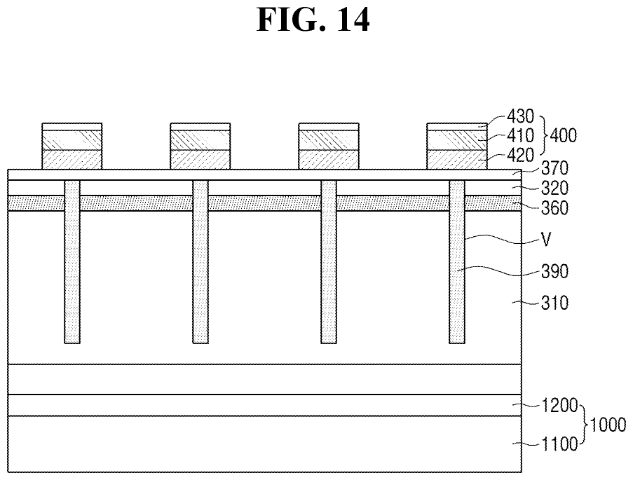

Thereafter, referring to FIGS. 14 through 16, semiconductor rods 300, which may be spaced apart from one another, may be formed by etching the first and second semiconductor material layers 310 and 320, the light-emitting material layer 360, and the electrode material layer 370. The etching of the first and second semiconductor material layers 310 and 320, the light-emitting material layer 360, and the electrode material layer 370 may include forming mask layers 400 on the electrode material layers 370 and performing a second etching process (“2^{nd} etching”), which etches the first and second semiconductor material layers 310 and 320 along the mask layers 400.

Specifically, referring to FIG. 14, the mask layers 400 may be formed on the electrode material layers 370. The mask layers 400 may include first insulating mask layers 410 and second insulating mask layers 420, which may be disposed on the electrode material layers 370, and mask patterns 430, which may be disposed on the second insulating mask layers 420. The mask layers 400 may have a shape in which the first insulating mask layers 410 and the second insulating mask layers 420 may be etched along the gaps between the mask patterns 430. The first and second semiconductor material layers 310 and 320 may be etched along the gaps between the mask layers 400. The mask layers 400 may have the same diameter or width. Parts of each of the first and second semiconductor material layers 310 and 320 that overlap the mask layers 400 and may thus not be etched away may form the semiconductor rods 300, which form the light-emitting elements ED. Accordingly, the mask layers 400 may be disposed to overlap the voids V and the filler layers 39 in a thickness direction so that the light-emitting elements ED may include the voids V and the filler layers 39. The diameter of the mask layers 400 may be substantially the same as the diameter of the light-emitting elements ED. As the mask layers 400 have the same diameter or width, the light-emitting elements ED may have substantially the same diameter.

The first insulating mask layers 410 and the second insulating mask layers 420 may include an insulating material, and the mask patterns 430 may include a metallic material. For example, the first insulating mask layers 410 and the second insulating mask layers 420 may include SiOₓ, SiNₓ, or SiOₓN_{y}, but the disclosure is not limited thereto. For example, the mask patterns 430 may include a metal such as chromium (Cr), but the disclosure is not limited thereto.

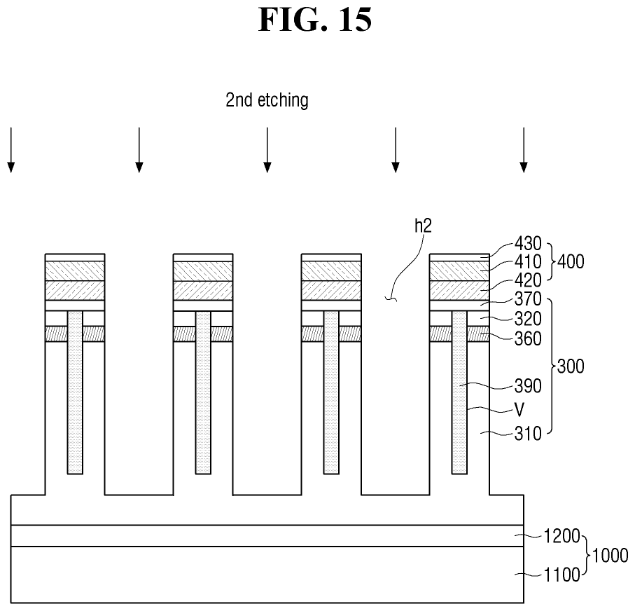

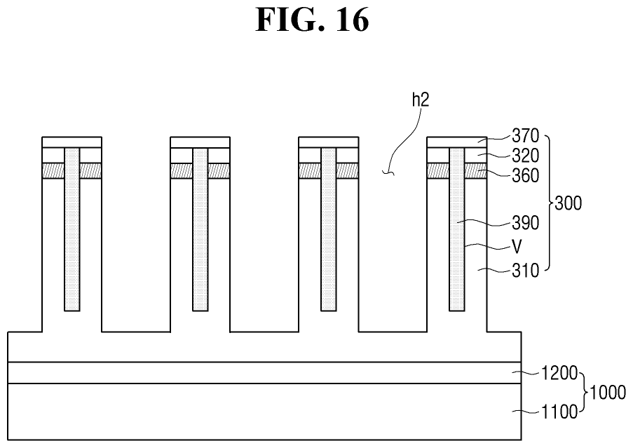

Thereafter, referring to FIGS. 15 and 16, second holes h2 may be formed by performing the second etching process (“2^{nd} etching”) to etch the first and second semiconductor material layers 310 and 320 along the mask layers 400. The second etching process, like the first etching process, may be performed in the direction perpendicular to the top surface of the base substrate 1000.

The second etching process may be performed by a dry etching method, a wet etching method, a reactive ion etching (ME) method, or an inductively-coupled plasma-reactive ion etching (ICP-RIE) method. The dry etching method may allow anisotropic etching and may thus be suitable for vertically etching the first and second semiconductor material layers 310 and 320. During the second etching process, Cl₂ or O₂ may be used as an etchant, but the disclosure is not limited thereto.

As a result of the second etching process, the semiconductor rods 300, which may be spaced apart from one another, may be formed on the base substrate 1000. Each of the semiconductor rods may include the first semiconductor material layer 310, the light-emitting material layer 360, the second semiconductor material layer 320, and the electrode material layer 370, and may further include a void V and a filler material layer 390, which may be formed in each of the first semiconductor material layer 310, the light-emitting material layer 360, and the second semiconductor material layer 320. During the second etching process, the lower part of the first semiconductor material layer 310 may not be completely etched, but may remain. Parts of the first semiconductor material layer 310 included in the semiconductor rods 300 may be connected to one another. An insulating material layer 380 may be formed on the outer surfaces of each of the semiconductor rods 300, thereby forming the light-emitting elements ED.

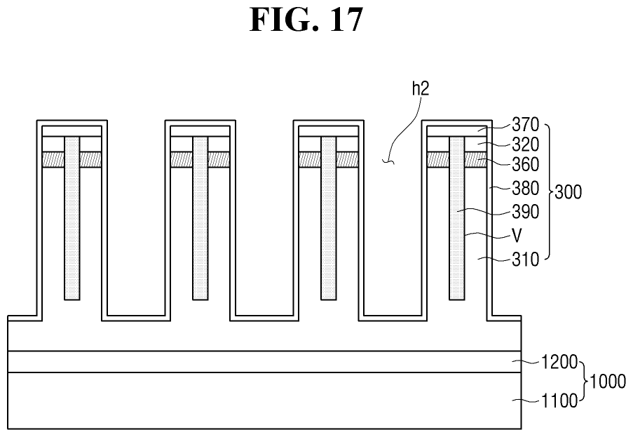

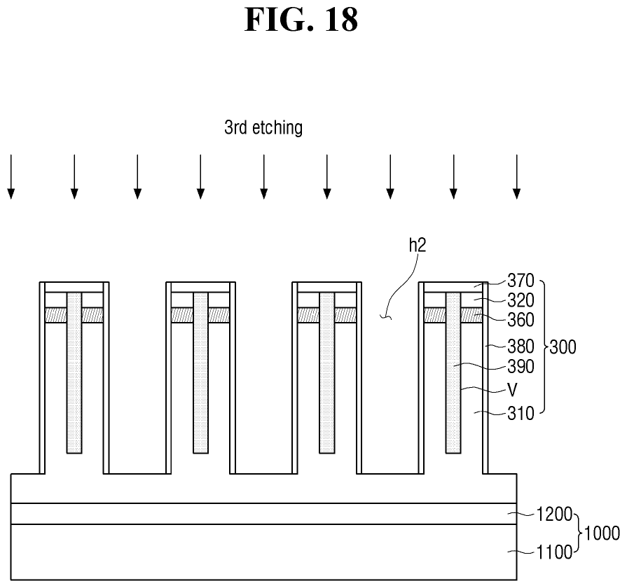

Thereafter, referring to FIGS. 17 and 18, the insulating material layer 380, which surrounds parts of the sides of the semiconductor rods 300, may be formed. The insulating material layer 380 may be formed to surround the outer surfaces of each of the semiconductor rods 300, and a third etching process (“3^{rd} etching”), which partially removes the insulating material layer 380 to expose the top surfaces of the semiconductor rods 300, may be performed.

The insulating material layer 380, which may be an insulating layer formed on the outer surfaces of each of the semiconductor rods 300, may be formed by applying an insulating material to the outer surfaces of each of the semiconductor rods 300, which may be vertically etched, or immersing the outer surfaces of each of the semiconductor rods 300 in an insulating material, but the disclosure is not limited thereto. For example, the insulating material layer 380 may be formed by atomic layer deposition (ALD) or chemical vapor deposition (CVD).

The insulating material layer 380 may be formed on the sides and the top surfaces of the semiconductor rods 300 and on parts of the first semiconductor material layer 310 exposed between the semiconductor rods 300. The insulating material layer 380 may be partially removed by an anisotropic etching process such as a dry etching process or an etch-back process. The upper part of the insulating material layer 380 may be etched so that the electrode material layer 370 may be exposed, and the electrode material layer 370 may also be partially etched. The thickness of the electrode layers 37 of the light-emitting elements ED may be less than the thickness of the electrode material layer 370.

The electrode material layer 370 is illustrated as having a flat top surface and having its top surface partially exposed, but the disclosure is not limited thereto. In other embodiments, parts of the insulating material layer 380 that surround the electrode material layer 370 may be formed to be curved. As not only the top surface, but also sides of the insulating material layer 380 may be partially removed, the insulating material layer 380 may be formed to have its end faces partially etched, surrounding multiple layers. As the upper part of the insulating material 380 may be removed, the outer surface of the insulating film 38 may be partially removed near the electrode layers 37 of the light-emitting elements ED.

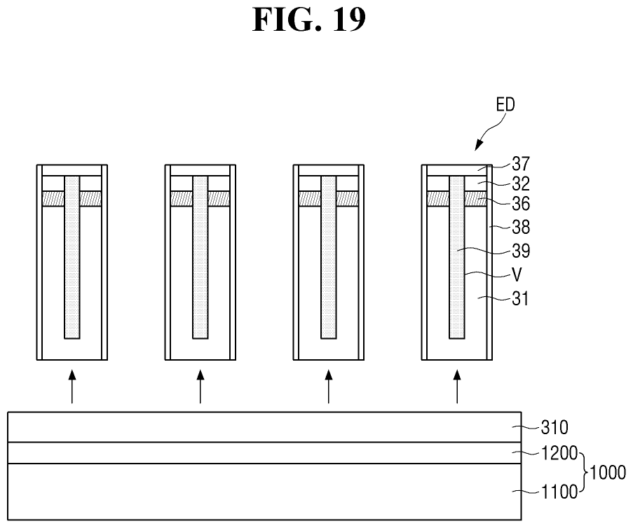

Referring to FIG. 19, the semiconductor rods 300 with the insulating material layer 380 formed thereon may be separated from the first semiconductor material layer 310. Once separated from the base substrate 1000, the semiconductor rods 300 may become the light-emitting elements ED. In this manner, the light-emitting elements ED, which have the voids V and the filler layers 39 disposed therein, may be obtained.

The light-emitting elements ED may have a diameter W2 of several nanometers or micrometers, and the diameter W1 of the voids V of the light-emitting elements ED may be less than the diameter W2 of the light-emitting elements ED. During the first etching process, which forms the first holes h1, the photoresist layers PR may be formed to have a relatively large aspect ratio in consideration that the voids V of the light-emitting elements ED may be formed to extend in a direction. In this case, high-resolution semiconductor equipment may be used, but the disclosure is not limited thereto. Instead, an etching process using a different material may be performed.

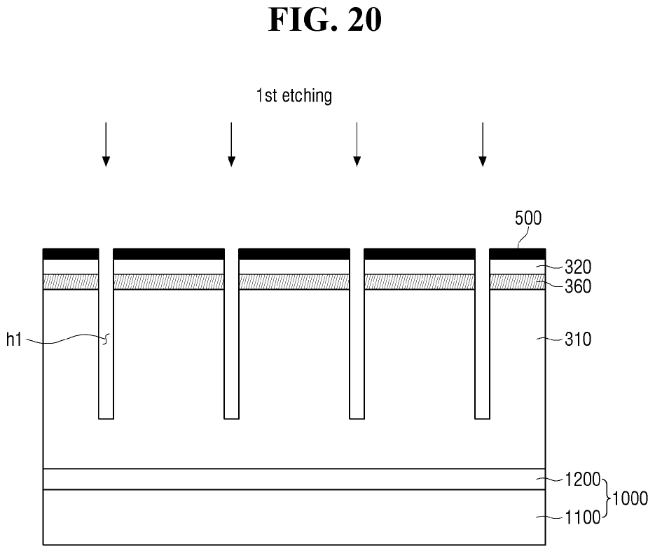

FIG. 20 is a schematic cross-sectional view illustrating a method of fabricating a light-emitting element according to another embodiment of the disclosure.

Referring to FIG. 20, during a first etching process (“1^{st} etching”), which forms first holes h1, hard mask layers 500 may be used instead of the photoresist layers PR. The hard mask layers 500, unlike the photoresist layers PR, may include a metal such as Cr and may be suitable for forming the first holes h1, which extend in a direction, without the need to have a large aspect ratio. As the hard mask layers 500, which may be thinner than the photoresist layers PR, include a relatively rigid metallic material, the hard mask layers 500 can be formed without using high-resolution semiconductor equipment. As the first etching process may be performed using the hard mask layers 500 to form light-emitting elements ED with a small diameter and form voids V, which have a smaller diameter than the light-emitting elements ED, in the light-emitting elements ED, the fabrication of the light-emitting elements ED can be facilitated.

Light-emitting elements according to other embodiments of the disclosure will hereinafter be described.

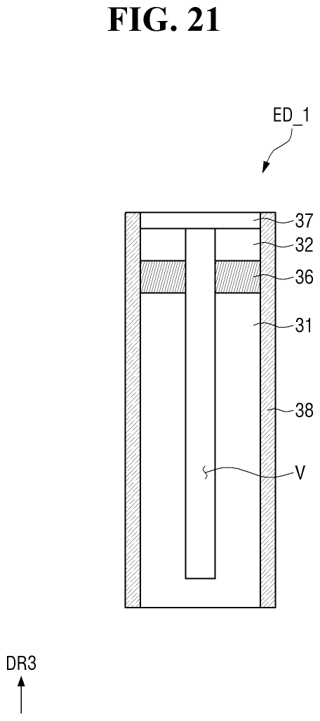

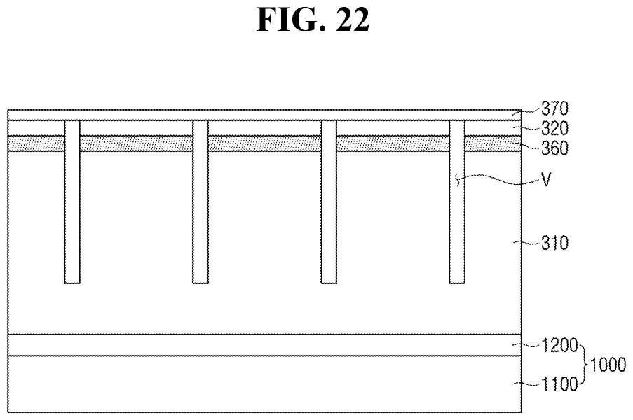

FIG. 21 is a schematic cross-sectional view of a light-emitting element according to another embodiment of the disclosure. FIG. 22 is a schematic cross-sectional view illustrating a method of fabricating the light-emitting element of FIG. 21.

Referring to FIG. 21, a light-emitting element ED_1 may include a void V, which may be formed in the light-emitting element ED_1, but a filler layer 39 may not be provided. Referring to FIG. 22, a filler material layer 390 may not be provided in first holes h1, and after a first etching process, an electrode material layer 370 may be formed on a second semiconductor material layer 320. An embodiment of FIG. 21 differs from an embodiment of FIG. 6 at least in that the light-emitting element ED_1 does not include a filler layer 39.

As the light-emitting element ED_1 includes the void V, the light-emitting element ED_1 may have a low specific gravity. If the void V may be filled with a filler layer 39, the light-emitting element ED_1 may be durable against external impact because of not being empty on the inside. However, if a sufficient durability against external impact can be guaranteed by appropriately controlling the length and width of the void V, the filler layer 39 may not be provided. In this manner, a light-emitting element ED_1 having a relatively low specific gravity and a relatively degree of alignment can be provided.

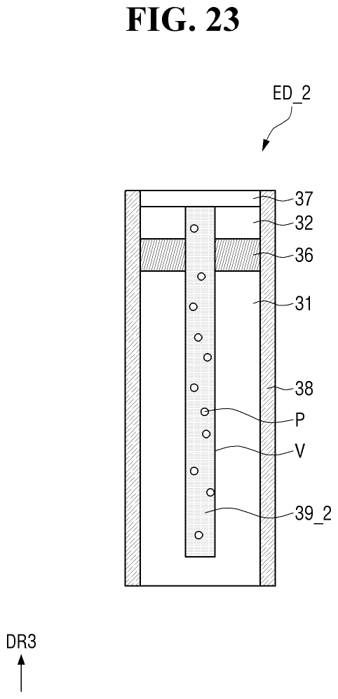

FIG. 23 is a schematic cross-sectional view of a light-emitting element according to another embodiment of the disclosure.

Referring to FIG. 23, a light-emitting element ED_2 may include a filler layer 39_2, which may be formed of a porous insulating material having multiple pores P. The filler layer 39_2, which may be an insulating layer that fills a void V formed in the light-emitting element ED_2, may lower the specific gravity of the light-emitting element ED_2. Various insulating materials having a lower specific gravity than first and second semiconductor layers 31 and 32 may be used to form the filler layer 39_2. As the filler layer 39_2 may be formed of a porous insulating material, the specific gravity of the light-emitting element ED_2 can be further lowered.

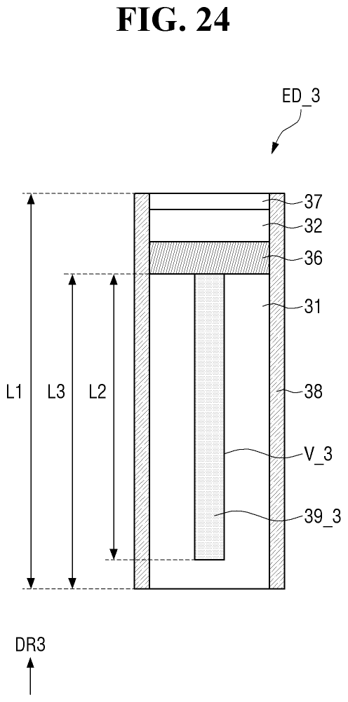

FIG. 24 is a schematic cross-sectional view of a light-emitting element according to another embodiment of the disclosure.

Referring to FIG. 24, a light-emitting element ED_3 may include a void V_3, which may be formed in a first semiconductor layer 31 and does not penetrate a light-emitting layer 36 and a second semiconductor layer 32. A filler layer 39_3 may be disposed in the void V_3 and may be surrounded by the first semiconductor layer 31. The void V_3 and the filler layer 39_3 may be relatively short.

The light-emitting element ED_3 may include the light-emitting layer 36 and may thus be able to emit light in response to electrical signals being applied to both end portions thereof. The optical efficiency of the light-emitting element ED_3 may be determined by factors such as the amount of light generated by the light-emitting layer 36 and the amount of light actually emitted out of the light-emitting element ED_3. The specific gravity of the light-emitting element ED_3 may be lowered due to the presence of the void V_3 in the light-emitting element ED_3. However, if the void V_3 may be formed to penetrate the light-emitting layer 36, the characteristics of the light-emitting layer 36 may change, and the optical efficiency of the light-emitting element ED_3 may become lower than designed. To prevent this, the void V_3 may be formed only in the first semiconductor layer 31 not to damage the light-emitting layer 36.

For example, the void V_3 may be formed by etching part of the first semiconductor layer 31, and the top surface of the void V_3 may be in contact with the bottom surface of the light-emitting layer 36. The void V_3 may extend from the interface between the first semiconductor layer 31 and the light-emitting layer 36 along the length direction of the light-emitting element ED_3. A length L2 of the void V_3 may be less than a length L3 of the first semiconductor layer 31. The side and the bottom surface of the filler layer 39_3, which may be disposed in the void V_3, may be in contact with the bottom surface of the first semiconductor layer 31, and the top surface of the filler layer 39_3 may be in contact with the bottom surface of the light-emitting layer 36.

The fabrication of the light-emitting element ED_3 may include depositing first and second semiconductor material layers 310 and 320 and performing a first etching process (“1^{st} etching”), which forms a first hole h1. The location and the length of the void V_3 may vary depending on when the first etching process may be performed during the fabrication of the light-emitting element ED_3.

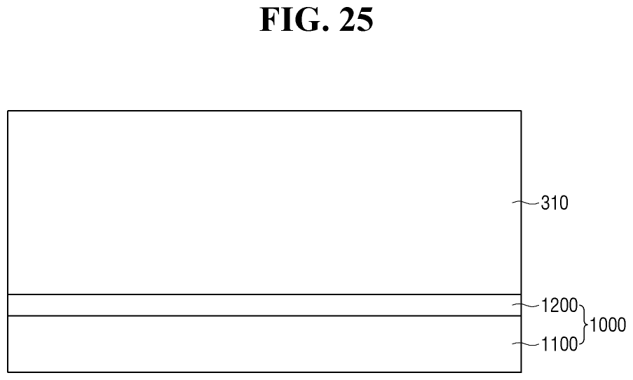

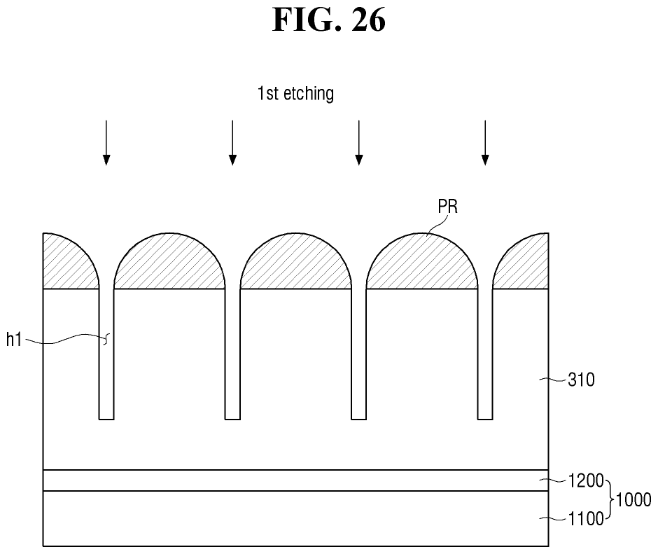

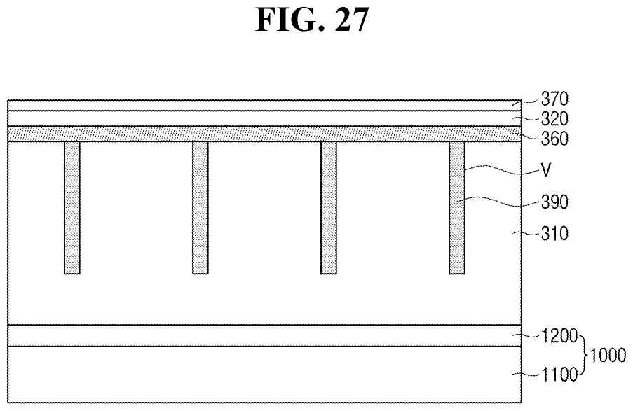

FIGS. 25 through 27 are schematic cross-sectional views illustrating steps of a method of fabricating the light-emitting element of FIG. 24.

Referring to FIGS. 25 through 27, a base substrate 1000 may be prepared, a first semiconductor material layer 310 may be formed on the base substrate 1000, and a first etching process (“1^{st} etching”), which forms first holes h1 by etching parts of the first semiconductor material layer 310, may be performed. In an embodiment of FIGS. 25 through 27, unlike in an embodiment of FIG. 10, the first etching process may be performed before the formation of a light-emitting material layer 360 and a second semiconductor material layer 320.

The first etching process may be performed in the same manner as already described above. Specifically, photoresist layers PR, which may be spaced apart from one another, may be formed on the first semiconductor material layer 310, and the first holes h1 may be formed by etching parts where the photoresist layers PR may not be disposed, in a direction perpendicular to the top surface of the base substrate 1000. The first holes h1 may be formed by etching parts of the first semiconductor material layer 310 and may have a smaller depth than the thickness of the first semiconductor material layer 310.

Thereafter, the photoresist layers PR may be removed, a filler material layer 390 may be disposed in the first holes h1, and the light-emitting element layer 360, the second semiconductor material layer 320, and an electrode material layer 370 may be formed on the first semiconductor material layer 310. Voids V, which may be formed by the first holes h1 in the first and second semiconductor material layers 310 and 320, the light-emitting material layer 360, and the electrode material layer 370, may penetrate the first semiconductor material layer 310, but not the light-emitting material layer 360 and the second semiconductor material layer 320. The filler material layer 390 may be disposed only in the first semiconductor material layer 310.

Although not specifically illustrated, a second etching process (“2^{nd} etching”) may be performed, an insulating material layer 380 may be formed, a third etching process (“3^{rd} etching”) may be performed, and semiconductor rods 300 may be separated from the base substrate 1000, thereby obtaining light-emitting elements ED_3.

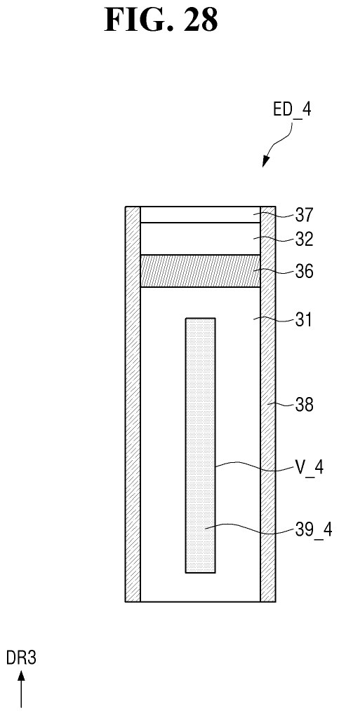

FIG. 28 is a schematic cross-sectional view of a light-emitting element according to another embodiment of the disclosure.

Referring to FIG. 28, a light-emitting element ED_4 may include a void V_4, which may be formed in a first semiconductor layer 31, and the top surface of the void V_4 may be spaced apart from a light-emitting layer 36. A filler layer 39_4 may be disposed in the first semiconductor layer 31 and may not be in contact with the light-emitting layer 36. An embodiment of FIG. 28 differs from an embodiment of FIG. 24 at least in that the lengths of the void V_4 and the filler layer 39_4 may be further reduced.

During the fabrication of the light-emitting element ED_4, a first etching process (“1^{st} etching”), which forms a first hole h1, may be performed, and a first semiconductor material layer 310 may be formed before the formation of a light-emitting material layer 360. Then, the void V_4, which may be formed by the first hole h1, may be formed in the first semiconductor material layer 310. The first semiconductor layer 31 may be longer than the other layers of the light-emitting element ED_4 and may account for a relatively large portion of the light-emitting element ED_4. If the void V_4 may be formed only in the first semiconductor layer 31, the specific gravity of the light-emitting element ED_4 can be lowered without damaging the light-emitting layer 36, a second semiconductor layer 32, and an electrode layer 37. As the void V_4 may be formed only in the first semiconductor layer 31 and the filler layer 39_4 may be disposed in the void V_4, damage that may be caused to the other layers of the light-emitting element ED_4 during the first etching process can be prevented.

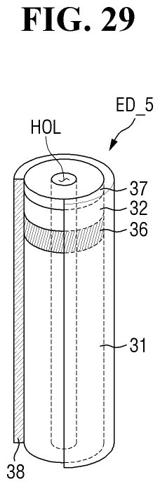

A void V of a light-emitting element ED may be formed not only in a first semiconductor layer 31, a light-emitting layer 36, and a second semiconductor layer 32, but may also completely penetrate the light-emitting element ED from one end to the other end of the light-emitting element ED. The light-emitting element ED may include a through hole (see “HOL” of FIG. 29), which extends longer than the void V in the length direction of the light-emitting element ED and penetrates the light-emitting element ED.

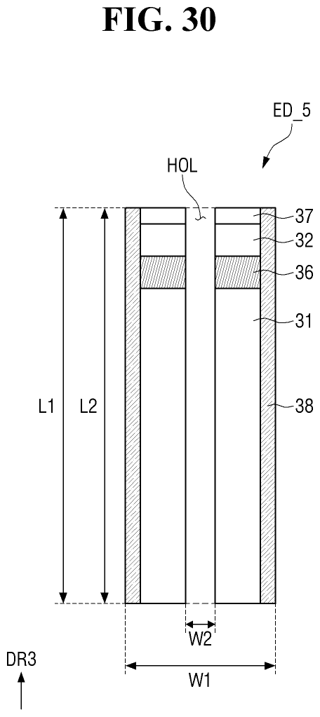

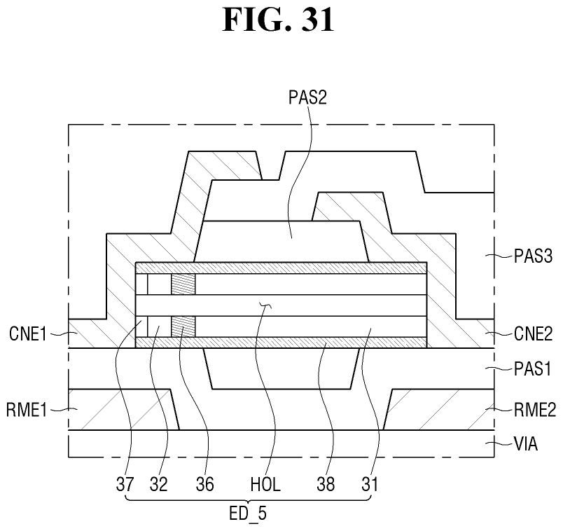

FIG. 29 is a schematic perspective view of a light-emitting element according to another embodiment of the disclosure. FIG. 30 is a schematic cross-sectional view of the light-emitting element of FIG. 29. FIG. 31 is a schematic cross-sectional view illustrating an area in a display device including the light-emitting element of FIG. 30 where the light-emitting element of FIG. 30 is disposed.

Referring to FIGS. 29 through 31, a light-emitting element ED_5 may include a through hole HOL, which penetrates the light-emitting element ED_5 in the length direction of the light-emitting element ED_5. The through hole HOL may extend from the bottom surface of a first semiconductor layer 31 to the top surface of an electrode layer 37, and may penetrate the light-emitting element ED_5, ranging from the first semiconductor layer 31 to a light-emitting layer 36 to a second semiconductor layer 32 to the electrode layer 37.

A length L2 of the through hole HOL may be the same as a length L1 of the light-emitting element ED_5. The through hole HOL may penetrate not only the light-emitting layer 36 and the second semiconductor layer 32, but also the first semiconductor layer 31 and the electrode layer 37. The light-emitting element ED_5 may include the through hole HOL, which may be longer than the void V of the light-emitting element ED of FIG. 5, and a diameter W2 of the through hole HOL may be relatively small. For example, the diameter W2 of the through hole HOL may be less than a diameter W1 of the light-emitting element ED_5 and may account for less than 50% of the diameter W1 of the light-emitting element ED_5. The diameter W2 of the through hole HOL may vary without affecting the electrical and optical characteristics of the first and second semiconductor layers 31 and 32 and the light-emitting layer 36, which may be penetrated by the through hole HOL.

A display device 10 may include the light-emitting element ED_5, which includes the through hole HOL. The light-emitting element ED_5 may be disposed such that the length direction of the light-emitting element ED_5 may be parallel to a direction in which electrodes RME may be spaced apart from each other and both end portions of the light-emitting element ED may be placed on the electrodes RME. The through hole HOL of the light-emitting element ED_5 may be arranged in parallel to the direction in which the electrodes RME may be spaced apart from each other. Both end surfaces of the light-emitting element ED_5 may be in contact with connecting electrodes CNE, and both sides of the through hole HOL may adjoin the connecting electrodes CNE. Due to the presence of the through hole HOL, the area by which the electrode layer 37 and the first semiconductor layer 31 may be in contact with the connecting electrodes CNE may be reduced. However, the diameter W2 of the through hole HOL may be controlled to the extent that the electrode layer 37 and the first semiconductor layer 31 may properly maintain their electrical connection to the connecting electrodes CNE.

As the through hole HOL completely penetrates the light-emitting element ED_5, a filler layer 39 may not be provided in the light-emitting element ED_5. If a filler layer 39 may be disposed in the through hole HOL, the filler layer 39 may flow from both ends of the light-emitting element ED_5 and may remain as a foreign material.

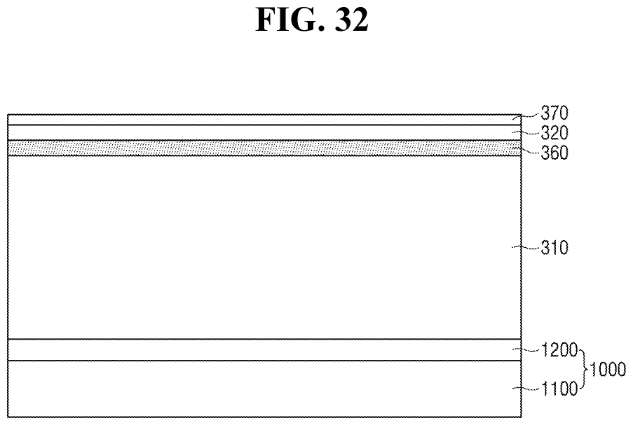

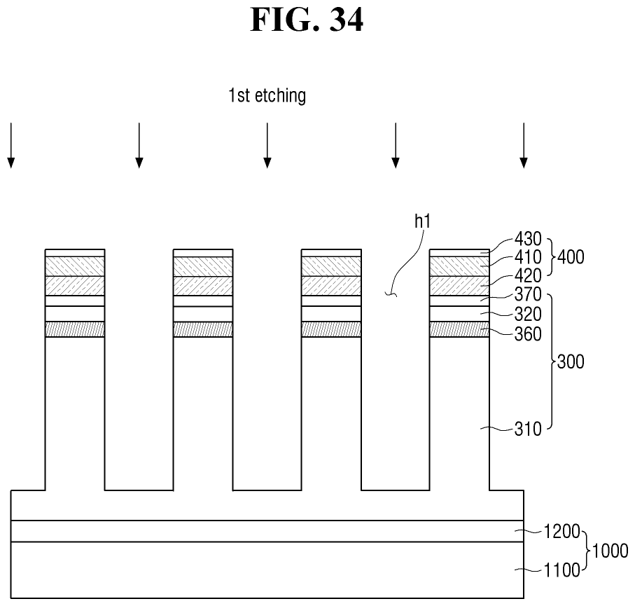

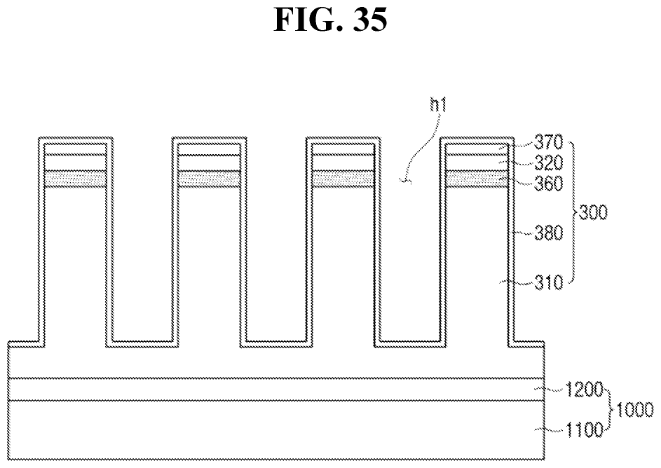

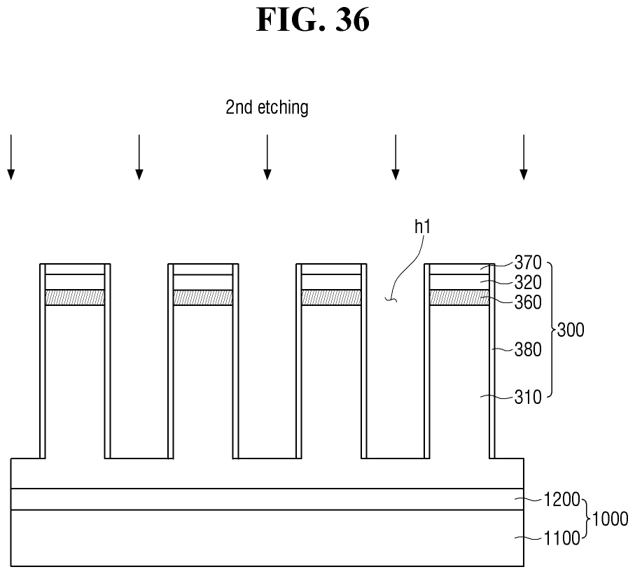

FIGS. 32 through 38 are schematic cross-sectional views illustrating a method of fabricating the light-emitting element of FIG. 29.

Referring to FIGS. 32 through 38, the formation of light-emitting elements ED_5 may include performing a first etching process (“1^{st} etching”), which forms first holes h1, performing a second etching process (“2^{nd} etching”), which etches an insulating material layer 380, and performing a third etching process (“3^{rd} etching”), which forms through holes HOL in semiconductor rods 300. In an embodiment of FIGS. 32 through 38, unlike in the previous embodiments, the etching of first and second semiconductor material layers 310 and 320 or the etching of the semiconductor rods 300 may be performed as a final etching process before the separation of the semiconductor rods 300 from a base substrate 1000.

Specifically, referring to FIG. 32, the first semiconductor material layer 310, a light-emitting material layer 360, the second semiconductor material layer 320, and an electrode material layer 370 may be sequentially formed on the base substrate 1000. The first semiconductor material layer 310, the light-emitting material layer 360, the second semiconductor material layer 320, and the electrode material layer 370 may form first semiconductor layers 31, light-emitting layers 36, second semiconductor layers 32, and electrode layers 37, respectively, of the light-emitting elements ED_5 and may be the same as their respective counterparts of any one of the previous embodiments. An embodiment of FIGS. 32 through 38 differs from the previous embodiments at least in that the electrode material layer 370 may be formed when the first semiconductor material layer 310, the light-emitting material layer 360, and the second semiconductor material layer 320 are yet to be etched.

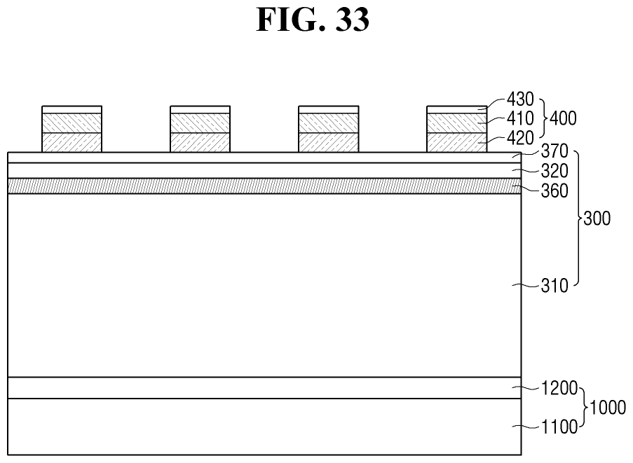

Thereafter, referring to FIGS. 33 through 36, the first etching process, which etches the first semiconductor material layer 310, the light-emitting material layer 360, the second semiconductor material layer 320, and the electrode material layer 370 using mask layers 400, may be performed, and an insulating material layer 380 may be formed on the outer surfaces of each of the semiconductor rods 300. As already mentioned above, the semiconductor rods 300 may be formed through the first etching process by forming the mask layers 400, which may be spaced apart from one another, on the electrode material layer 370 and etching parts where the mask layers 400 may not be disposed, in a direction perpendicular to the top surface of the base substrate 1000.

After the formation of the semiconductor rods 300 through the first etching process, an insulating material layer 380, which surrounds the outer surfaces of each of the semiconductor rods 300, may be formed. The insulating material layer 380 may be formed to completely surround the outer surfaces of each of the semiconductor rods 300 and may then be subjected to the second etching process. The formation of the insulating material layer 380 is as already mentioned above. In an embodiment of FIGS. 32 through 38, unlike in the previous embodiments, an etching process that etches the inside of each of the semiconductor rods 300 with the insulating material layer 380 formed thereon may not be performed. Thus, a void V and a filler material layer 390 may not be formed in each of the semiconductor rods 300.

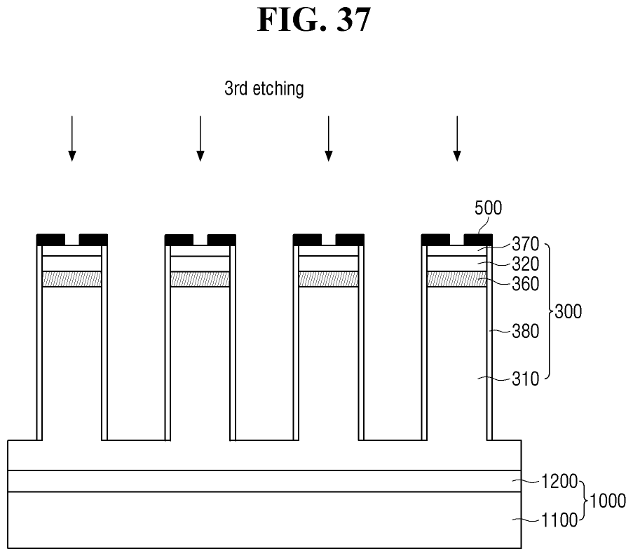

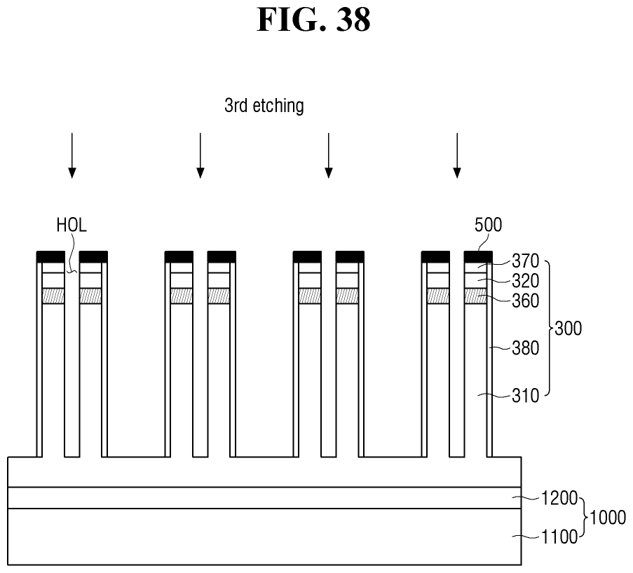

Thereafter, referring to FIGS. 37 and 38, hard mask layers 500 may be formed on the semiconductor rods 300 with the insulating material layer 380 formed thereon, and the third etching process, which etches the first and second semiconductor material layers 310 and 320, the light-emitting material layer 360, and the electrode material layer 370 in each of the semiconductor rods 300, may be performed. As a result of the third etching process, through holes HOL, which penetrate the first and second semiconductor material layers 310 and 320, the light-emitting material layer 360, and the electrode material layer 370, may be formed in the semiconductor rods 300. The hard mask layers 500 are illustrated as being used as masks during the formation of the through holes HOL, but the disclosure is not limited thereto. During the third etching process, photoresist layers may be used as the hard mask layers 500.

Thereafter, although not specifically illustrated, the semiconductor rods 300 with the through holes HOL formed therein may be separated from the base substrate 1000, thereby obtaining the light-emitting elements ED_5. During the formation of the light-emitting elements ED_5, an etching process for forming the through holes HOL, i.e., the third etching process, may be performed after the formation of the insulating material layer 380. As a result, light-emitting elements ED_5 that may be completely penetrated by the through holes HOL can be formed and can have a lower specific gravity than light-emitting elements not including the through holes HOL. Accordingly, the degree of alignment of light-emitting elements in a display device 10 can be improved.

In concluding the detailed description, those skilled in the art will appreciate that many variations and modifications can be made to the embodiments without substantially departing from the principles of the disclosure. Therefore, the disclosed embodiments are used in a generic and descriptive sense only and not for purposes of limitation.

What is claimed is:

1. A light-emitting element comprising:
a first semiconductor layer doped with an n-type dopant;
a second semiconductor layer disposed on the first semiconductor layer and doped with a p-type dopant;
a light-emitting layer disposed between the first and second semiconductor layers;
an electrode layer disposed on the second semiconductor layer;
an insulating film surrounding at least an outer surface of the light-emitting layer; and
a void formed on the first semiconductor layer, the void extending in a direction in which the first semiconductor layer, the light-emitting layer, and the second semiconductor layer are disposed.

2. The light-emitting element of claim 1, further comprising:
a filler layer disposed in the void, the filler layer having a lower specific gravity than a lower specific gravity of the first semiconductor layer, a lower specific gravity of the light-emitting layer, and a lower specific gravity of the second semiconductor layer.

3. The light-emitting element of claim 2, wherein the filler layer includes an insulating material different from the insulating film.

4. The light-emitting element of claim 3, wherein
the filler layer includes polyimide, and
the insulating film includes at least one of silicon oxide, silicon nitride, and silicon oxynitride.

5. The light-emitting element of claim 2, wherein the filler layer includes a porous material.

6. The light-emitting element of claim 2, wherein
the void penetrates the light-emitting layer and the second semiconductor layer and is formed by etching part of the first semiconductor layer, and
the filler layer is in contact with the first semiconductor layer, the light-emitting layer, and the second semiconductor layer.

7. The light-emitting element of claim 6, wherein a top surface of the filler layer physically contacts a bottom surface of the electrode layer.

8. The light-emitting element of claim 6, wherein the void and the filler layer are shorter than the light-emitting element.

9. The light-emitting element of claim 2, wherein the void is formed in the first semiconductor layer and is shorter than the light-emitting element.

10. The light-emitting element of claim 9, wherein
the void extends from an interface between the light-emitting layer and the first semiconductor layer, and
a top surface of the filler layer physically contacts a bottom surface of the light-emitting layer.

11. The light-emitting element of claim 9, wherein
the void is formed only in the first semiconductor layer to be spaced apart from the light-emitting layer, and
the filler layer does not physically contact the light-emitting layer.

12. The light-emitting element of claim 1, wherein the void forms a through hole, which penetrates both a top surface and a bottom surface of the light-emitting element through the first semiconductor layer, the light-emitting layer, the second semiconductor layer, and the electrode layer.

13. The light-emitting element of claim 12, wherein the through hole and the light-emitting element have a same length.

14. A display device comprising:
a first electrode and a second electrode disposed on a substrate to be spaced apart from each other;
a first insulating layer disposed on the first electrode and the second electrode;
a light-emitting element disposed on the first insulating layer, the light-emitting element having a first end portion disposed on the first electrode, and a second end portion disposed on the second electrode;
a second insulating layer disposed on the light-emitting element;
a first connecting electrode disposed on the first electrode, on the second insulating layer, the first connecting electrode electrically contacting the first end portion;
a second connecting electrode disposed on the second electrode, on the second insulating layer, the second connecting electrode electrically contacting the second end portion; and
a third insulating layer disposed on the second insulating layer and the second connecting electrode, below the first connecting electrode,
wherein the light-emitting element includes:
a first semiconductor layer;
a second semiconductor layer;
a light-emitting layer, which is disposed between the first semiconductor layer and the second semiconductor layer;
an electrode layer, which is disposed on the second semiconductor layer;
an insulating film, which surrounds at least an outer surface of the light-emitting layer; and
a void, which is formed in the first semiconductor layer, the light-emitting layer, and the second semiconductor layer and extends in a length direction of the light-emitting element.

15. The display device of claim 14, wherein
the void penetrates the second semiconductor layer and the light-emitting layer and meets a bottom surface of the electrode layer, and
the light-emitting element further includes a filler layer disposed in the void.

16. The display device of claim 14, wherein the void penetrates the first semiconductor layer and the electrode layer to form a through hole, which penetrates both the first and second end portions of the light-emitting element.

17. A method of fabricating light-emitting elements, comprising:
forming a first semiconductor material layer, a light-emitting material layer, and a second semiconductor material layer on a base substrate;
performing a first etching step of forming first holes by etching the first semiconductor material layer, the light-emitting material layer, and the second semiconductor material layer in a direction perpendicular to a top surface of the base substrate;
forming a filler material layer in each of the first holes and forming an electrode material layer on the second semiconductor material layer;
forming second holes by etching the first semiconductor material layer, the light-emitting material layer, the second semiconductor material, and the electrode material layer in the direction perpendicular to the top surface of the base substrate, thereby forming semiconductor rods, which are spaced apart from one another; and
separating the semiconductor rods with the insulating material layer formed thereon from the base substrate.

18. The method of claim 17, wherein the performing the first etching step comprises:
forming the first holes to penetrate the second semiconductor material layer and the light-emitting material layer, but not the first semiconductor material layer.

19. The method of claim 17, wherein
the forming the semiconductor rods comprises:
forming mask layers, which are spaced apart from one another, on the electrode material layer; and
performing a second etching step of etching parts where the mask layers are not disposed, and
the mask layers overlap the filler material layer.

20. The method of claim 17, wherein the performing the first etching process comprises:
forming photoresist layers or hard mask layers on the second semiconductor material layer; and
dry-etching parts where the photoresist layers or the hard mask layers are not disposed.
